(19) United States
(12) Patent Application Publication
(10) Pub. No.: US 2024/0290778 A1
(43) Pub. Date: Aug. 29, 2024

(54) SEMICONDUCTOR DEVICE

(71) Applicant: ROHM CO., LTD., Kyoto (JP)

(72) Inventors: Tadao YUKI, Kyoto (JP); Satoshi TANAKA, Kyoto (JP)

(21) Appl. No.: 18/656,653

(22) Filed: May 7, 2024

Related U.S. Application Data
(63) Continuation of application No. PCT/JP2022/037107, filed on Oct. 4, 2022.

(30) Foreign Application Priority Data
Nov. 18, 2021 (JP) 2021-187649

(51) Int. Cl. H01L 27/02; H01L 27/06; H01L 29/78

(52) U.S. Cl. CPC H01L 27/0296; H01L 27/0255; H01L 27/0629; H01L 29/7817

(57) ABSTRACT

A semiconductor device includes, as each of a first electrostatic protection diode, a second electrostatic protection diode, and a third electrostatic protection diode, a lateral NDMOS transistor thyristorized by having a p-type dopant region formed in its drain. For example, the anode of the first electrostatic protection diode is connected to a first signal terminal; the anode of the second electrostatic protection diode is connected to a second signal terminal; and the anode of the third electrostatic protection diode is connected to a ground terminal. The cathodes of the first, second, and third electrostatic protection diodes are connected together.

### CROSS-REFERENCE TO RELATED APPLICATIONS

This nonprovisional application is a continuation application of International Patent Application No. PCT/JP2022/037107 filed on Oct. 4, 2022, which claims priority Japanese Patent Application No. 2021-187649 filed on Nov. 18, 2021, the entire contents of which are hereby incorporated by reference.

### TECHNICAL FIELD

The disclosure herein relates to a semiconductor device that has a diode structure of an EIS (electrode-insulator-semiconductor) type, that is, a stacked structure of an electrode, an insulator, and a semiconductor.

### BACKGROUND ART

Patent Document 1 identified below discloses a semiconductor device with an EIS diode structure. This semiconductor device includes an n-type semiconductor substrate, a p-type base region, an n-type source region, a p-type anode region, an n-type cathode region, a gate insulation film, and a gate electrode.

The base region is formed in a superficial part of the semiconductor substrate. The source region is formed in a superficial part of the base region, at an interval inward from an edge part of the base region, and demarcates a channel region from the semiconductor substrate. The anode region is formed in a superficial part of the base region, in a region different from the source region. The cathode region is formed in a superficial part of the semiconductor substrate, at an interval from the base region, and demarcates a drift region from the base region. The gate insulation film covers the channel region at the top of the semiconductor substrate. The gate electrode is formed on the gate insulation film, and faces the channel region across the gate insulation film. The gate electrode is electrically connected to the source region and to the anode region.

### CITATION LIST

### Patent Literature

Patent Document 1: JP-A-2007-27228

### BRIEF DESCRIPTION OF DRAWINGS

FIG. 1 is a circuit diagram showing the electrical structure of a principal portion of a semiconductor device according to a first embodiment of the present disclosure.

FIG. 2 is a perspective view of the semiconductor device 1 in FIG. 1.

FIG. 3 is an enlarged view of region III in FIG. 2.

FIG. 4 is an enlarged view of a principal part of the structure in FIG. 3.

FIG. 5 is a diagram showing the structure in FIG. 4 with the part on top of a semiconductor layer removed.

FIG. 6 is an enlarged view of region VI in FIG. 5.

FIG. 7 is a sectional view along line VII-VII in FIG. 5.

FIG. 8 is a sectional view along line VIII-VIII in FIG. 5.

FIG. 9 is a graph showing the current-voltage response of a reverse current prevention diode according to a comparative example.

FIG. 10 is a graph showing the current-voltage response of a reverse current prevention diode according to the first embodiment.

FIG. 11 is a circuit diagram showing the electrical structure of a principal portion of a semiconductor device according to a second embodiment of the present disclosure.

FIG. 12 is a diagram showing one example of electrostatic protection circuits according to the second embodiment.

FIG. 13 is a diagram showing one example of an element layout according to the second embodiment.

FIG. 14 is a diagram showing the current-voltage response of the electrostatic protection circuits according to the second embodiment.

FIG. 15 is a diagram showing one example of electrostatic protection circuits according to a third embodiment.

FIG. 16 shows a diagram showing one example of an element layout according to the third embodiment.

FIG. 17 is a diagram showing the current-voltage response of the electrostatic protection circuits according to the third embodiment.

FIG. 18 is a diagram showing one example of an electrostatic protection circuit according to a fourth embodiment.

### DESCRIPTION OF EMBODIMENTS

### First Embodiment

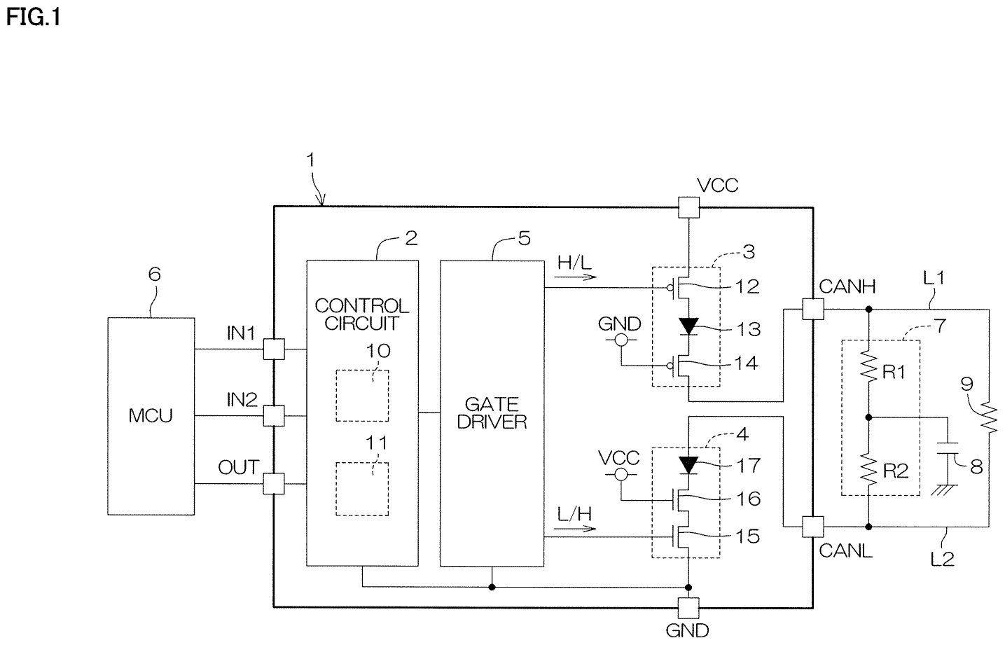

FIG. 1 is a circuit diagram showing the electrical structure of a principal portion of a semiconductor device 1 according to a first embodiment of the present disclosure. The semiconductor device 1 is a transceiver integrated circuit device for use in a CAN (controller area network), which is a kind of vehicle onboard network. The semiconductor device 1 includes an input terminal IN, an output terminal OUT, a supply terminal VCC, a ground terminal GND, a high-side terminal CANH, a low-side terminal CANL, a control circuit 2, a high-side output circuit 3, a low-side output circuit 4, and a gate driver circuit 5.

Any number of input terminals can be provided. FIG. 1 shows an example where the input terminal IN comprises a first input terminal IN1 and a second input terminal IN2. FIG. 1 shows an example where: a microcomputer 6 is connected to the input terminal IN and to the output terminal OUT; and a resistor division circuit 7, a capacitor 8, and a terminal resistor 9 are connected between the high-side terminal CANH and the low-side terminal CANL.

The control circuit 2 is electrically connected to the plurality of input terminals IN, to the output terminal OUT, and to the ground terminal GND. The control circuit 2 includes an electrical signal generation circuit 10 and a functional circuit 11. The electrical signal generation circuit 10 generates, based on input signals from the input terminals IN, predetermined electrical signals for driving different circuits, and feeds these electrical signals to the different circuits. The functional circuit 11 generates, based on input signals from the input terminals IN and electrical signals from the different circuits, an electrical signal for monitoring the different circuits, and feeds this electrical signal to the output terminal OUT.

The functional circuit 11 includes, for example, one or more protection circuits for protecting different circuits. The functional circuit 11 can include, as one example of protection circuits, at least one of an overcurrent protection circuit, an overheat protection circuit, and an undervoltage malfunctioning prevention circuit. The overcurrent protection circuit protects different circuits from an overcurrent. The overheat protection circuit protects different circuits from overheating. The undervoltage malfunctioning prevention circuit prevents different circuits from malfunctioning in an undervoltage condition.

The high-side output circuit 3 is electrically connected to the supply terminal VCC, to the high-side terminal CANH, and to the gate driver circuit 5. The high-side output circuit 3 has a series circuit that includes a first driving transistor 12, a first reverse current prevention diode 13, and a first protection transistor 14. The first driving transistor 12 and the first protection transistor 14 are each a MISFET (metal-insulator-semiconductor field-effect transistor) of a p type (first or second polarity type).

The gate of the first driving transistor 12 is electrically connected to the gate driver circuit 5. The source of the first driving transistor 12 is connected to the supply terminal VCC. The anode of the first reverse current prevention diode 13 is connected to the drain of the first driving transistor 12. The gate of the first protection transistor 14 is electrically connected to the ground terminal GND. The source of the first protection transistor 14 is connected to the cathode of the first reverse current prevention diode 13. The drain of the first protection transistor 14 is connected to the high-side terminal CANH. If the voltage at the high-side terminal CANH is negative, the first protection transistor 14 prevents outward passage of a current via the high-side terminal CANH (to the terminal resistor 9).

The low-side output circuit 4 is electrically connected to the ground terminal GND, to the low-side terminal CANL, and to the gate driver circuit 5. The low-side output circuit 4 has a series circuit that includes a second driving transistor 15, a second protection transistor 16, and a second reverse current prevention diode 17. The second driving transistor 15 and the second protection transistor 16 are each a MISFET of a polarity type opposite to the p type.

The gate of the second driving transistor 15 is electrically connected to the gate driver circuit 5. The source of the second driving transistor 15 is connected to the ground terminal GND. The gate of the second protection transistor 16 is connected to the supply terminal VCC. The source of the second protection transistor 16 is connected to the drain of the second driving transistor 15. The cathode of the second reverse current prevention diode 17 is connected to the drain of the second protection transistor 16. The anode of the second reverse current prevention diode 17 is connected to the low-side terminal CANL. If the voltage at the low-side terminal CANL is positive, the second protection transistor 16 prevents inward passage of a current via the low-side terminal CANL from outside (from the terminal resistor 9).

The gate driver circuit 5 is electrically connected to the control circuit 2, to the high-side output circuit 3, to the low-side output circuit 4, and to the ground terminal GND. According to an electrical signal from the control circuit 2, the gate driver circuit 5 generates a first control signal H/L with a predetermined pulse waveform and a second control signal L/H with a predetermined pulse waveform. The second control signal L/H is the inversion signal of the first control signal H/L. The first control signal H/L is fed to the gate of the first driving transistor 12, and the second control signal L/H is fed to the gate of the second driving transistor 15.

The resistor division circuit 7 includes a first resistor R1 and a second resistor R2. One terminal of the first resistor R1 is connected to the high-side terminal CANH. One terminal of the second resistor R2 is connected to the other terminal of the first resistor R1. The other terminal of the second resistor R2 is connected to the low-side terminal CANL. One terminal of the capacitor 8 is connected to the junction between the first and second resistors R1 and R2. The other terminal of the capacitor 8 is grounded. One terminal of the terminal resistor 9 is connected via a first bus line L1 to the high-side terminal CANH. The other terminal of the terminal resistor 9 is connected via a second bus line L2 to the low-side terminal CANL.

When a low-level first control signal H/L is fed to the first driving transistor 12 and a high-level second control signal L/H is fed to the second driving transistor 15, the first and second driving transistors 12 and 15 are on. As a result, a bus signal SH of 3.5 V (standard value) is output to the high-side terminal CANH and a bus signal SL of 1.5 V (standard value) is output to the low-side terminal CANL (a dominant state).

By contrast, when a high-level first control signal H/L is fed to the first driving transistor 12 and a low-level second control signal L/H is fed to the second driving transistor 15, the first and second driving transistors 12 and 15 are off. As a result, a bus signal SH of 2.5 V (standard value) is output to the high-side terminal CANH and a bus signal SL of 2.5 V (standard value) is output to the low-side terminal CANL (a recessive state). The structure of the semiconductor device 1 will now be described.

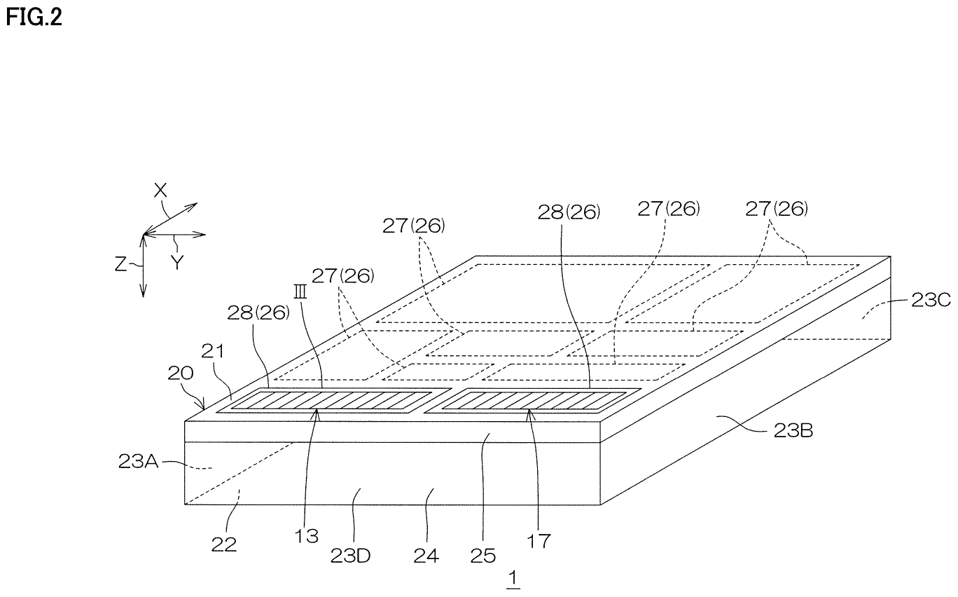

FIG. 2 is a perspective view of the semiconductor device 1 in FIG. 1. FIG. 2 omits illustration of the input terminal IN, the supply terminal VCC, the ground terminal GND, the high-side terminal CANH, and the low-side terminal CANL mentioned above.

Referring to FIG. 2, in this embodiment, the semiconductor device 1 includes a semiconductor chip 20 made of silicon. The semiconductor chip 20 is formed in a parallelepiped shape. The semiconductor chip 20 has a first main face 21 at one side, a second main face 22 at the other side, and a first to a fourth side face 23A to 23D that connect between the first and second main faces 21 and 22.

The first and second main faces 21 and 22 are each formed in a quadrangular shape as seen in a plan view from a normal direction Z to it (hereinafter simply “in a plan view”). The first and second side faces 23A and 23B extend along a first direction X and face each other along a second direction Y orthogonal to the first direction X. The third and fourth side faces 23C and 23D extend along the second direction Y and face each other along the first direction X.

In this embodiment, the semiconductor chip 20 has a stacked structure that includes a semiconductor substrate 24 of a p type (first conductivity type) and a semiconductor layer 25 of an n type (second conductivity type), i.e., the conductivity type opposite to the p type, that are formed in this order from the second main face 22 side to the first main face 21 side. The semiconductor substrate 24 forms the second main face 22 and parts of the side faces 23A to 23D. The semiconductor layer 25 forms the first main face 21 and parts of the side faces 23A to 23D.

The p-type dopant concentration in the semiconductor substrate 24 can be 1×10¹³ cm⁻³ or more but 1×10¹⁶ cm⁻³ or less. The thickness of the semiconductor substrate 24 can be 100 μm or more but 1000 μm or less, and can preferably be 200 μm or more but 700 μm or less.

In this embodiment, the semiconductor layer 25 is an epitaxial layer formed on the semiconductor substrate 24. The n-type dopant concentration in the semiconductor layer 25 can be 1×10¹⁴ cm⁻³ or more but 1×10¹⁶ cm⁻³ or less. The thickness of the semiconductor layer 25 is less than the thickness of the semiconductor substrate 24. The thickness of the semiconductor layer 25 can be 1 μm or more but 50 μm or less, and can preferably be 5 μm or more but 20 μm or less.

The semiconductor chip 20 includes a plurality of device regions 26 that are defined in the first main face 21. The plurality of device regions 26 include one or more (in this embodiment, a plurality of) functional device regions 27 and one or more (in this embodiment, two) diode regions 28. Any number of functional device regions 27, and diode regions 28, can be arranged in any way.

The functional device regions 27 are regions where various functional devices are formed that constitute parts or wholes of the control circuit 2, the gate driver circuit 5, the first driving transistor 12, the first protection transistor 14, the second driving transistor 15, the second protection transistor 16, and the like mentioned above. The functional devices are formed using the first main face 21 and/or a superficial part of the first main face 21. The functional devices can include at least one of a semiconductor switching device, a semiconductor rectifying device, and a passive device. The functional devices can include a circuit network comprising a combination of a semiconductor switching device, a semiconductor rectifying device, and a passive device.

The semiconductor switching device can include at least one of a MISFET, a CMIS (complementary MISFET), a BJT (bipolar junction transistor), an IGBT (insulated-gate bipolar junction transistor), and a JFET (junction field-effect transistor). The semiconductor switching device includes the first driving transistor 12, the first protection transistor 14, the second driving transistor 15 and the second protection transistor 16 mentioned above.

The semiconductor rectifying device can include at least one of a pn-junction diode, a pin-junction diode, a Zener diode, a Schottky-barrier diode, and a fast-recovery diode. The passive device can include at least one of a resistor, a capacitor, and an inductor.

The plurality of diode regions 28 are defined at an interval from the plurality of functional device regions 27. The plurality of diode regions 28 are regions where the first and second reverse current prevention diodes 13 and 17 mentioned above are respectively formed. The plurality of diode regions 28 all have a similar internal structure. Now, taking the diode region 28 (region III in FIG. 2) of the first reverse current prevention diode 13 as an example, a description will be given of a specific structure of a diode region 28. The description of the diode region 28 of the first reverse current prevention diode 13 applies to the diode region 28 of the second reverse current prevention diode 17.

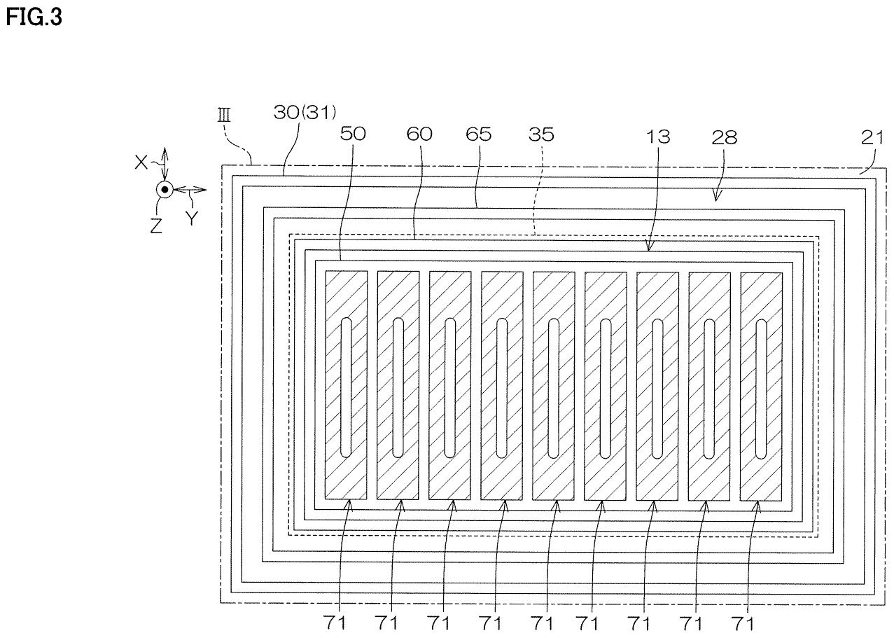

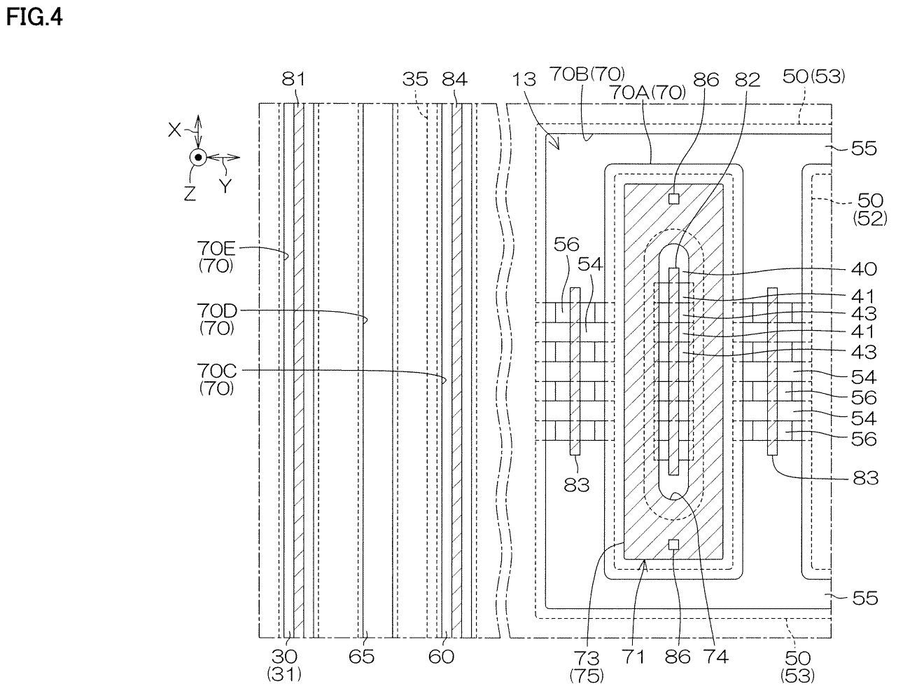

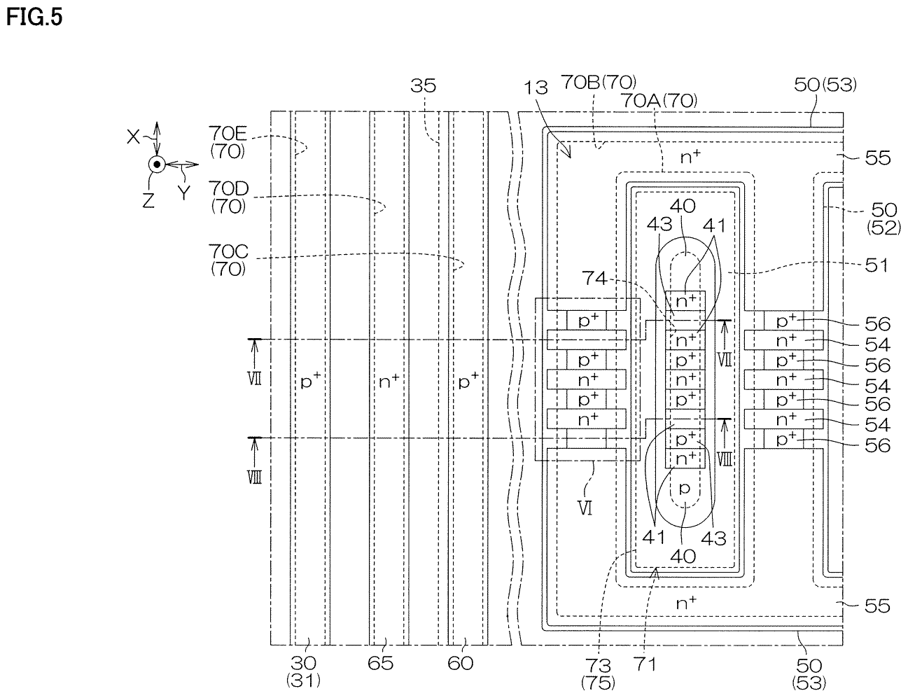

FIG. 3 is an enlarged view of region III in FIG. 2. FIG. 4 is an enlarged view of a principal part of the structure in FIG. 3. FIG. 5 is a diagram showing the structure in FIG.

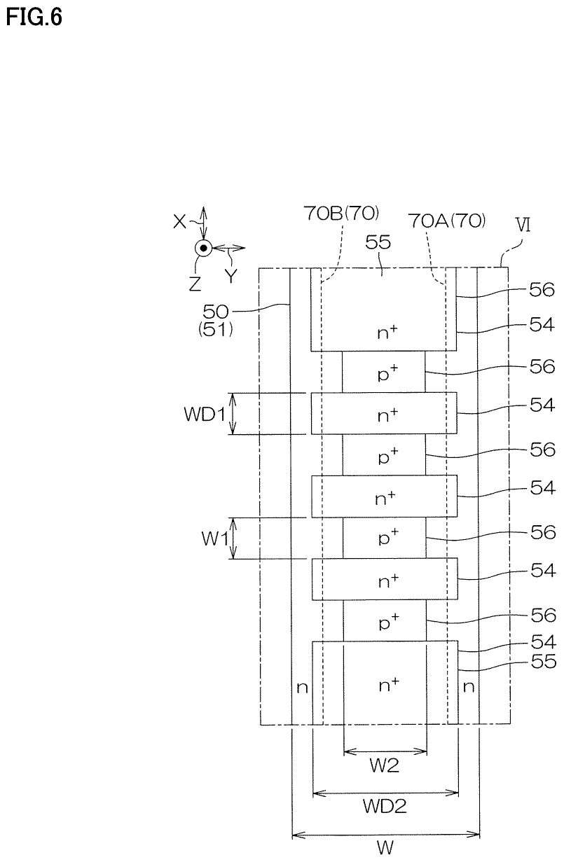

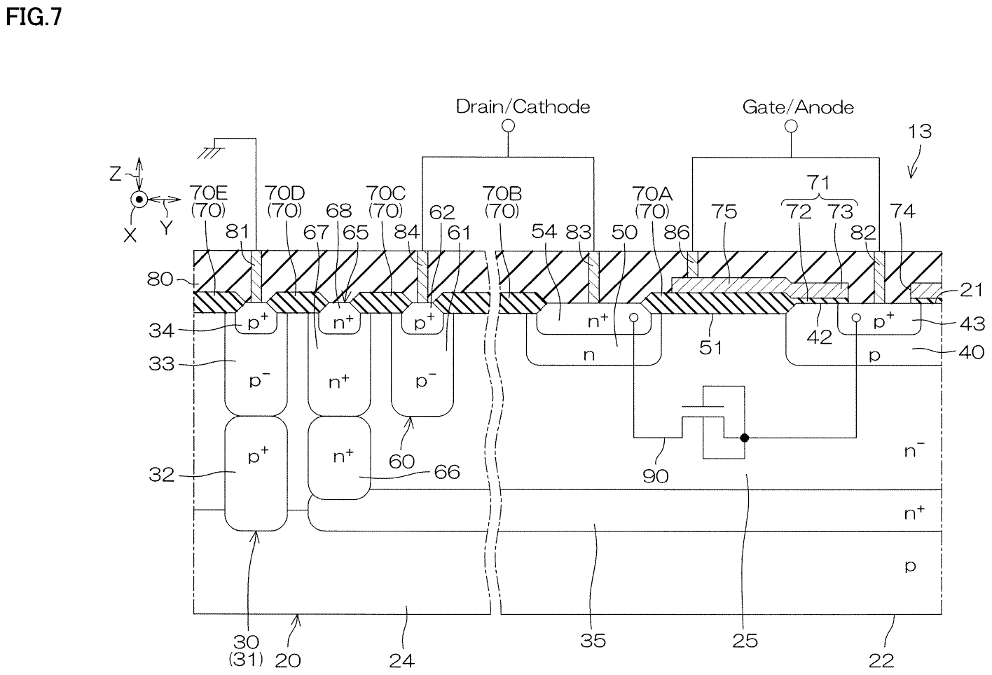

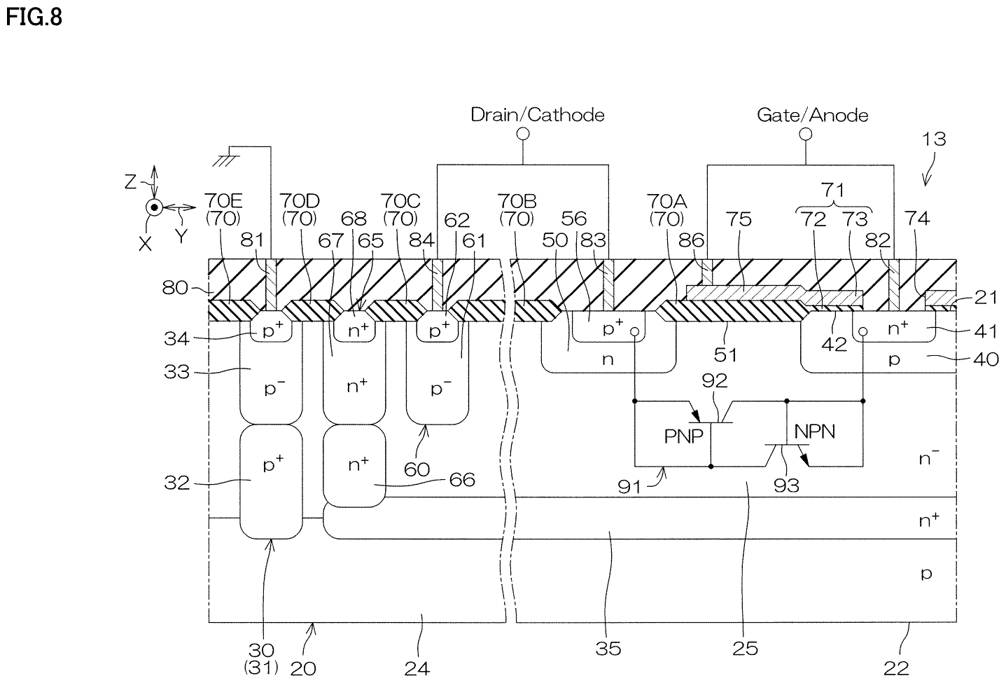

4 with the part on top of the semiconductor layer 25 removed. FIG. 6 is an enlarged view of region VI in FIG. 5. FIG. 7 is a sectional view along line VII-VII in FIG. 5. FIG. 8 is a sectional view along line VIII-VIII in FIG. 5.

Referring to FIGS. 3 to 8, the semiconductor device 1 includes a region separation structure 30 that defines, on the first main face 21, a partial region of the semiconductor layer 25 as a diode region 28. The region separation structure 30 electrically separates the diode region 28 from the plurality of functional device regions 27. The region separation structure 30 is formed, as seen in a plan view, in a ring shape (in this embodiment, a quadrangular ring shape) surrounding the diode region 28. The planar shape of the diode region 28 is adjusted by the inner edge of the region separation structure 30. In this embodiment, the high-side output circuit 30 defines the diode region 28 in a quadrangular shape as seen in a plan view.

In this embodiment, the region separation structure 30 is a p-type column region 31 formed in the shape of a wall in the semiconductor layer 25 so as to be electrically connected to the semiconductor substrate 24. The column region 31 includes a column embedded region 32, a column well region 33, and a column contact region 34.

The column embedded region 32 is formed to bridge across the boundary between the semiconductor substrate 24 and the semiconductor layer 25, and is electrically connected to the semiconductor substrate 24. While, in this embodiment, one column embedded region 32 is formed, any number of column embedded regions 32 can be provided so long as they are electrically connected to the semiconductor substrate 24. A plurality of column embedded regions 32 can be stacked from the boundary toward the first main face 21. The p-type dopant concentration in the column embedded region 32 can be 1×10¹⁶ cm⁻³ or more but 1×10²⁰ cm⁻³ or less.

The column well region 33 is formed in a superficial part of the first main face 21.

Specifically, the column well region 33 is formed in the semiconductor layer 25, in a region between the first main face 21 and the column embedded region 32, and is electrically connected to the column embedded region 32. The column well region 33 can have a p-type dopant concentration less than the p-type dopant concentration in the column embedded region 32. The p-type dopant concentration in the column well region 33 can be 1×10¹⁵ cm⁻³ or more but 1×10¹⁷ cm⁻³ or less.

The column contact region 34 is formed in a superficial part of the column well region 33, at an interval from the bottom of the column well region 33 toward the first main face 21. The column contact region 34 has a p-type dopant concentration more than the p-type dopant concentration in the column well region 33. The p-type dopant concentration in the column contact region 34 can be 1×10¹⁸ cm⁻³ or more but 1×10²⁰ cm⁻³ or less.

The semiconductor device 1 includes an n-type embedded region 35 that is formed in the diode region 28 so as to bridge across the boundary between the semiconductor substrate 24 and the semiconductor layer 25. In FIGS. 3 to 5, the embedded region 35 is indicated by broken lines. The embedded region 35 has an n-type dopant concentration more than the n-type dopant concentration in the semiconductor layer 25. The n-type dopant concentration in the embedded region 35 can be 1×10¹⁶ cm⁻³ or more but 1×10²⁰ cm⁻³ or less.

The embedded region 35 is formed at an interval from the first main face 21 toward the semiconductor substrate 24, and faces the first main face 21 across part of the semiconductor layer 25. The embedded region 35 is formed at an interval inward from the region separation structure 30. In this case, part of the n-type dopant in the embedded region 35 can be diffused in a peripheral part of the diode region 28. That is, the embedded region 35 can have a concentration gradient such that the n-type dopant concentration in it is less in an peripheral part of the diode region 28 than in an inner part of the diode region 28.

The semiconductor device 1 includes one or more (in this embodiment, a plurality of) p-type base regions 40 formed in the diode region 28, in a superficial part of the first main face 21. The plurality of base regions 40 are each formed as part of the anode region of the first reverse current prevention diode 13. The p-type dopant concentration in each base region 40 can be 1×10¹⁵ cm⁻³ or more but 1×10¹⁷ cm⁻³ or less.

Specifically, the plurality of base regions 40 are each formed in a region surrounded in an edge part of the embedded region 35. The plurality of base regions 40 are formed at an interval from the embedded region 35 toward the first main face 21, and face the embedded region 35 across part of the semiconductor layer 25. In this embodiment, the plurality of base regions 40 are each formed in the shape of a strip extending along the first direction X, and are formed at intervals along the second direction Y. Thus the plurality of base regions 40 are formed, as seen in a plan view, in the shape of stripes extending along the first direction X.

The semiconductor device 1 includes one or more (in this embodiment, a plurality of) n-type source regions 41 formed in a superficial part of each base region 40. The source regions 41 have an n-type dopant concentration more than the n-type dopant concentration in the semiconductor layer 25. The n-type dopant concentration in each source region 41 can be 1×10¹⁸ cm⁻³ or more but 1×10²⁰ cm⁻³ or less.

The plurality of source regions 41 are formed in a superficial part of each base region 40 at intervals along the first direction X. The plurality of source regions 41 are each formed at an interval inward from an edge part of each base region 40, and each demarcate, from the semiconductor layer 25, a channel region 42 formed by a superficial part of the base region 40. The plurality of source regions 41 are formed at an interval inward from opposite edge parts of each base region 40 along the first direction X, and expose the opposite edge parts of each base region 40 on the first main face 21.

The plurality of source regions 41 can have any planar shape. The plurality of source regions 41 can be formed, as seen in a plan view, in a square shape or in a circular shape (which can be an elliptical shape). In this embodiment, the plurality of source regions 41 are each formed in the shape of a strip extending along the second direction Y.

The semiconductor device 1 includes one or more (in this embodiment, a plurality of) p-type base contact regions 43 formed in a superficial part of each base region 40, in regions different from the source regions 41. The plurality of base contact regions 43 are each formed as part of the anode region of the first reverse current prevention diode 13. The base contact regions 43 each have a p-type dopant concentration more than the p-type dopant concentration in each base region 40. The p-type dopant concentration in each base contact region 43 can be 1×10¹⁸ cm⁻³ or more but 1×10²⁰ cm⁻³ or less.

In this embodiment, the plurality of base contact regions 43 are formed in a superficial part of each base region 40, at intervals along the first direction X.

Specifically, the plurality of base contact regions 43 are formed alternately with the plurality of source regions 41 so as to sandwich one source region 41 at a place. Thus a loop array that includes a plurality of source regions 41 and a plurality of base contact regions 43 is formed in a superficial part of each base region 40. In this embodiment, both the starting point and the ending point of the loop array are formed with a source region 41. Instead, either or both of the starting point and the ending point of the loop array can be formed with a base contact region 43.

The plurality of base contact regions 43 may have any planar shape. The plurality of base contact regions 43 can be formed, as seen in a plan view, in a square shape or in a circular shape (which can be an elliptical shape). In this embodiment, the plurality of base contact regions 43 are each formed in the shape of a strip extending along the second direction Y.

The semiconductor device 1 includes one or more (in this embodiment, a plurality of) n-type well regions 50 formed in the diode region 28, in a superficial part of the first main face 21 at an interval from the base region 40. The number of well regions 50 is adjusted according to the number of base regions 40. The plurality of well regions 50 are each formed as part of the cathode region of the first reverse current prevention diode 13. The well regions 50 each demarcate a drift region 51 from the base region 40. The drift region 51 is contiguous with the channel region 42. The well regions 50 each have a n-type dopant concentration more than the n-type dopant concentration in the semiconductor layer 25. The n-type dopant concentration in each well region 50 can be 1×10¹⁵ cm⁻³ or more but 1×10¹⁷ cm⁻³ or less.

The plurality of well regions 50 are formed at an interval from the embedded region 35 toward the first main face 21, and face the embedded region 35 across the semiconductor layer 25. The plurality of well regions 50 are each formed, as seen in a plan view, in a ring shape (in this embodiment, a quadrangular ring shape) surrounding the corresponding one base region 40. Thus, each drift region 51 is demarcated in a ring shape as seen in a plan view. The well regions 50 can have any planar shape, and can be formed in an oval ring shape.

Referring to FIG. 6, the plurality of well regions 50 each have a well width W. The well width W is a width along the direction orthogonal to the direction in which the well regions 50 extend. The well width W can be 0.5 μm or more but 5 μm or less, and can preferably be 1 μm or more but 4 μm or less.

The plurality of well regions 50 each include a first region 52 and a second region 53 that extend in different directions. The first region 52 extends along the longer sides of the base region 40 (i.e., along the first direction X). The second region 53 extends along the shorter sides of the base region 40 (i.e., along the second direction Y). The well width W of the second region 53 can be different from the well width W of the first region 52. In this embodiment, the well width W of the second region 53 is less than the well width W of the first region 52. Needless to say, the well width W of the second region 53 can be equal to, or more than, the well width W of the first region 52.

In this embodiment, the first regions 52 of the plurality of well regions 50 are formed to be unitary (continuous) among a plurality of base regions 40 that are adjacent to each other. Thus the plurality of well regions 50 form, as seen in a plan view, one ladder well region that surrounds, in the shape of a ladder, the plurality of base regions 40. The plurality of first regions 52 are formed alternately with the plurality of base regions 40 along the second direction Y so as to sandwich one drift region 51 at a place.

The semiconductor device 1 includes one or more (in this embodiment, a plurality of) n-type drain regions 54 formed in a superficial part of the plurality of well regions 50. The plurality of drain regions 54 are each formed as part of the cathode region of the first reverse current prevention diode 13. The drain regions 54 each have an n-type dopant concentration more than the n-type dopant concentration in each well region 50. The n-type dopant concentration in each drain region 54 can be 1×10¹⁸ cm⁻³ or more but 1×10²⁰ cm⁻³ or less.

The plurality of drain regions 54 are formed in a superficial part of the first region 52 of each well region 50, at an interval from the second region 53 of each well region 50. Specifically, the plurality of drain regions 54 are formed only in a superficial part of the first region 52 of each well region 50, not in the second region 53. In this embodiment, the plurality of drain regions 54 are formed in a superficial part of the first region 52, only in a region facing the base regions 40. The first region 52 of the well region 50 is formed as an effective region where the plurality of drain regions 54 form a main current path.

The plurality of drain regions 54 are formed in a superficial part of the first region 52 of each well region 50, at intervals along the first direction X. The plurality of drain regions 54 face the plurality of source regions 41 in one-to-one correspondence along the second direction Y. With this structure, the plurality of drain regions 54 form, in the drift region 51, a current path that connects the plurality of source regions 41 together across the shortest distance. This helps reduce the resistance component across the current path. The plurality of drain regions 54 do not necessarily need to face the plurality of source regions 41 in one-to-one correspondence. The plurality of drain regions 54 can face the plurality of base contact regions 43 in one-to-one correspondence along the second direction Y.

The plurality of drain regions 54 are formed at an interval, along the second direction Y, inward from an edge part of the first region 52 of each well region 50. The plurality of drain regions 54 can have any planar shape. The plurality of drain regions 54 can be formed, as seen in a plan view, in a square shape or in a circular shape (which can be an elliptical shape). In this embodiment, the plurality of drain regions 54 are each formed in the shape of a strip extending along the second direction Y.

Referring to FIG. 6, the plurality of drain regions 54 each have a first drain width WD1 along the first direction X and a second drain width WD2 along the second direction Y. The first drain width WD1 can be 0.1 μm or more but 3 μm or less, and can preferably be 0.5 μm or more but 2.5 μm or less. The first drain width WD1 can be equal to the width of the source region 41 along the first direction X. Preferably, the second drain width WD2 is less than the well width W of the well region 50. The second drain width WD2 can be 0.1 μm or more but 4 μm or less, and can preferably be 0.5 μm or more but 3.5 μm or less.

The semiconductor device 1 includes a plurality of n-type outer drain regions 55 that are formed in superficial parts of the plurality of well regions 50, in regions outside the drain regions 54. The outer drain regions 55 have an n-type dopant concentration more than the n-type dopant concentration in each well region 50. The outer drain regions 55 have an n-type dopant concentration equal to the n-type dopant concentration in the drain regions 54.

The plurality of outer drain regions 55 are formed in superficial parts of the second regions 53 of the plurality of well regions 50 respectively. Moreover, the plurality of outer drain regions 55 are, in each well region 50, lead out of the second region 53 into the first region 52 and are formed to be unitary (contiguous) with, of the plurality of drain regions 54, the two drain regions 54 located at opposite ends. The plurality of outer drain regions 55 are formed at an interval inward from an edge pars of each well region 50. The plurality of outer drain regions 55 suppress unwanted channel reversal in the well region 50.

The semiconductor device 1 includes one or more (in this embodiment, a plurality of) p-type dopant regions 56 formed in superficial parts of the plurality of well regions 50. The dopant regions 56 each have a p-type dopant concentration more than the p-type dopant concentration in each base region 40. The p-type dopant concentration in each dopant region 56 can be 1×10¹⁸ cm⁻³ or more but 1×10²⁰ cm⁻³ or less.

The plurality of dopant regions 56 are formed at an interval from the second region 53 of each well regions 50, in a superficial part of the first region 52 of each well region 50. Specifically, the plurality of dopant regions 56 are formed only in a superficial part of the first region 52 of each well region 50, not in the second region 53. In this embodiment, the plurality of dopant regions 56 are formed in a superficial part of the first region 52 of each well region 50, only in a region facing the base region 40 along the second direction Y.

The plurality of dopant regions 56 are formed in a superficial part of the first region 52 of each well region 50, at intervals along the first direction X. Specifically, the plurality of dopant regions 56 are formed, in a superficial part of the first region 52 of each well region 50, alternately with the plurality of drain regions 54 so as to sandwich one drain region 54 at a place. That is, the plurality of dopant regions 56 are electrically connected to the plurality of drain regions 54 along the first direction X, and are not electrically connected to the plurality of drain regions 54 along the second direction Y.

The plurality of dopant regions 56 are formed at an interval inward from an edge part of the first region 52 of each well region 50. That is, the plurality of dopant regions 56 are electrically connected to the well region 50 along the second direction Y. Preferably, edge parts of the plurality of dopant regions 56 facing the base region 40 are formed more inward of the well region 50 than edge parts of the plurality of drain regions 54 facing the base regions 40. In this embodiment, along the second direction Y, opposite edge parts of the plurality of dopant regions 56 are formed more inward of the well region 50 than opposite edge parts of the drain regions 54.

The plurality of dopant regions 56 face the plurality of base contact regions 43 along the second direction Y in one-to-one correspondence. The plurality of dopant regions 56 do not necessarily face the plurality of base contact regions 43 in one-to-one correspondence. In accordance with how the plurality of drain regions 54 are arrayed, the plurality of dopant regions 56 can face the plurality of source regions 41 along the second direction Y in one-to-one correspondence.

The plurality of dopant regions 56 can have any planar shape. The plurality of dopant regions 56 can be formed, as seen in a plan view, in a square shape or in a circular shape (which can be an elliptical shape). In this embodiment, the plurality of dopant regions 56 are each formed in the shape of a strip extending along the second direction Y.

Referring to FIG. 6, the plurality of dopant regions 56 have a first width W1 along the first direction X and a second width W2 along the second direction Y. The first width W1 can be 0.1 μm or more but 3 μm or less, and can preferably be 0.5 μm or more but 2.5 μm or less. The first width W1 can be equal to the first drain width WD1 of the drain region 54. The first width W1 can be equal to the width of the base contact region 43 along the first direction X. The second width W2 is less than the second drain width WD2 of the drain regions 54. The second width W2 can be 0.1 μm or more but 3.5 μm or less, and can preferably be 0.5 μm or more but 3 μm or less.

The semiconductor device 1 includes a p-type guard region 60 that is formed in the diode region 28, in a superficial part of the first main face 21 at an interval from the plurality of well regions 50 at the side opposite from the plurality of base regions 40. Specifically, the guard region 60 is formed in a superficial part of the first main face 21, in a region between the region separation structure 30 and the plurality of well regions 50.

The guard region 60 is formed at an interval from the embedded region 35 toward the first main face 21, and faces the embedded region 35 across part of the semiconductor layer 25. The guard region 60 is formed, as seen in a plan view, in a ring shape (in this embodiment, a quadrangular ring shape) surrounding the plurality of well regions 50 altogether. The guard region 60 cuts off a leak current path formed between the region separation structure 30 and the plurality of base regions 40.

The guard region 60 includes a guard well region 61 and a guard contact region 62. The guard well region 61 is formed in a superficial part of the first main face 21. Specifically, the guard well region 61 is formed in the semiconductor layer 25, at a depth between the first main face 21 and the column embedded region 32. The p-type dopant concentration in the guard well region 61 can be 1×10¹⁵ cm⁻³ or more but 1×10¹⁷ cm⁻³ or less.

The guard well region 61 can be formed at a depth equal to the depth of the column well region 33. The guard well region 61 can have a p-type dopant concentration equal to the p-type dopant concentration in the column well region 33. With this structure, the guard well region 61 and the column well region 33 can be formed in the same process.

The guard contact region 62 is formed at an interval from the bottom of the guard well region 61 toward the first main face 21, in a superficial part of the guard well region 61. The guard contact region 62 has a p-type dopant concentration more than the p-type dopant concentration in the guard well region 61. The p-type dopant concentration in the guard contact region 62 can be 1×10¹⁸ cm⁻³ or more but 1×10²⁰ cm⁻³ or less.

The guard contact region 62 can be formed at a depth equal to the depth of the column contact region 34. The guard contact region 62 can have a p-type dopant concentration equal to the p-type dopant concentration in the column contact region 34. With this structure, the guard contact region 62 and the column contact region 34 can be formed in the same process.

The semiconductor device 1 includes an n-type channel stop region 65 that is formed in the diode region 28, at an interval from the guard region 60 on the side opposite from the plurality of well regions 50. In the following description, “channel stop” is abbreviated to “CS”. The CS region 65 is formed in a superficial part of the first main face 21, in a region between the region separation structure 30 and the guard region 60. The CS region 65 is formed along the peripheral edge of the diode region 28. Specifically, the CS region 65 is formed, as seen in a plan view, in a ring shape (in this embodiment, a quadrangular ring shape) surrounding the guard region 60.

The CS region 65 is formed in the shape of a wall in the semiconductor layer 25 so as to be electrically connected to the embedded region 35. Specifically, the CS region 65 includes a CS embedded region 66, a CS well region 67, and a CS superficial region 68.

The CS embedded region 66 is formed to bridge across the boundary between the embedded region 35 and the semiconductor layer 25, and is electrically connected to the embedded region 35. While, in this embodiment, one CS embedded region 66 is formed, any number of CS embedded regions 66 can be provided so long as they are electrically connected to the embedded region 35. A plurality of CS embedded regions 66 can be stacked from the embedded region 35 toward the first main face 21. The n-type dopant concentration in the CS embedded region 66 can be 1×10¹⁶ cm⁻³ or more but 1×10²⁰ cm⁻³ or less.

The CS well region 67 is formed in a superficial part of the first main face 21. Specifically, the CS well region 67 is formed in the semiconductor layer 25, in a region between the first main face 21 and the CS embedded region 66, and is electrically connected to the CS embedded region 66. The CS well region 67 can have an n-type dopant concentration less than the n-type dopant concentration in the CS embedded region 66. The n-type dopant concentration of the CS well region 67 can be 1×10¹⁶ cm⁻³ or more but 1×10²⁰ cm⁻³ or less.

The CS superficial region 68 is formed in a superficial part of the CS well region 67, at an interval from the bottom of the CS well region 67 toward the first main face 21. The CS superficial region 68 has an n-type dopant concentration more than the n-type dopant concentration in the CS well region 67. The n-type dopant concentration in the CS superficial region 68 can be 1×10¹⁸ cm⁻³ or more but 1×10²⁰ cm⁻³ or less. The CS superficial region 68 can have an n-type dopant concentration equal to the n-type dopant concentration in the source regions 41 (drain regions 54).

The semiconductor device 1 includes an insulation film 70 that selectively coats the first main face 21. In this embodiment, the insulation film 70 is a field oxidation film. A field oxidation film can be called a LOCOS (local oxidation of silicon) film. The insulation film 70 is formed on the first main face 21 so as to expose the region separation structure 30, the plurality of base regions 40, the plurality of well regions 50, the guard region 60, and the CS region 65 while coating the drift regions 51. Specifically, the insulation film 70 includes a plurality of first insulation films 70A, one second insulation film 70B, one third insulation film 70C, one fourth insulation film 70D, and one fifth insulation film 70E.

The plurality of first insulation films 70A are formed respectively in regions between the corresponding base regions 40 and the corresponding well regions 50 so as to coat the corresponding drift regions 51. The first insulation films 70A are each formed in a ring shape surrounding the corresponding base region 40. An inner end part of each first insulation film 70A coats an edge part of the base region 40 while exposing the channel regions 42, the source regions 41, and the base contact regions 43.

An outer end part of each first insulation film 70A coats an inner edge part of the well region 50 while exposing an inner part of the well region 50, the drain regions 54, the outer drain regions 55, and the dopant regions 56. Specifically, an outer end part of each first insulation film 70A coats edge parts of the plurality of drain regions 54 (outer drain regions 55) while exposing edge parts of the plurality of dopant regions 56. Thus an outer end part of each first insulation film 70A exposes the well region 50 in a region between itself and edge parts of the plurality of dopant regions 56.

The second insulation film 70B is formed in a region between the well region 50 and the guard region 60. The second insulation film 70B is formed, as seen in a plan view, in a ring shape surrounding the well region 50. An inner end part of the second insulation film 70B coats an outer edge part of the well region 50 while exposing the outer drain regions 55. Specifically, an inner end part of the second insulation film 70B coats edge parts of the plurality of outer drain regions 55 while exposing inward parts of the plurality of outer drain regions 55.

An inner end part of the second insulation film 70B further coats outer edge parts of the outermost well regions 50 while exposing an inward part of the well regions 50, the drain regions 54, the outer drain regions 55, and the dopant regions 56. Specifically, an inner end part of the second insulation film 70B coats edge parts of the plurality of drain regions 54 (outer drain regions 55) while exposing edge parts of the plurality of dopant regions 56. Thus an inner end part of the second insulation film 70B exposes the well regions 50 in a region between itself and the edge parts of the plurality of dopant regions 56. An outer end part of the second insulation film 70B coats an edge part of the guard region 60 while exposing an inward part of the guard region 60.

The third insulation film 70C is formed in a region between the guard region 60 and the CS region 65. The third insulation film 70C is formed, as seen in a plan view, in a ring shape surrounding the guard region 60. An inner end part of the third insulation film 70C coats an outer edge part of the guard region 60 while exposing an inward part of the guard region 60. An outer end part of the third insulation film 70C coats an inner edge part of the CS region 65 while exposing an inward part of the CS region 65.

The fourth insulation film 70D is formed in a region between the CS region 65 and the region separation structure 30 (column region 31). The fourth insulation film 70D is formed, as seen in a plan view, in a ring shape surrounding the CS region 65. An inner end part of the fourth insulation film 70D coats an outer edge part of the CS region 65 while exposing an inward part of the CS region 65. An outer end part of the fourth insulation film 70D coats an inner edge part of the region separation structure 30 (column region 31) while exposing an inward part of the region separation structure 30 (column region 31).

The fifth insulation film 70E is formed in a region outside the region separation structure 30 (column region 31). The fifth insulation film 70E coats an outer edge part of the region separation structure 30 (column region 31) while exposing an inward part of the region separation structure 30 (column region 31).

The semiconductor device 1 includes a plurality of gate structures 71 that are formed in the diode region 28, on top of the first main face 21. The plurality of gate structures 71 are formed respectively on top of the plurality of channel regions 42 exposed through the insulation film 70. That is, the plurality of gate structures 71 are formed respectively in regions surrounded by inner end parts of the plurality of first insulation films 70A. The plurality of gate structures 71 each has a stacked structure that includes a gate insulation film 72 and a gate electrode 73 stacked in this order from the first main face 21 side.

The gate insulation film 72 has a thickness smaller than the thickness of the insulation film 70. The gate insulation film 72 can contain silicon oxide. The gate insulation film 72 coats the channel regions 42, edge parts of the source regions 41, and edge parts of the base contact regions 43. Specifically, the gate insulation film 72 is formed, as seen in a plan view, in a ring shape having an inner end part and an outer end part.

The inner end part of the gate insulation film 72 defines a contact opening 74. The contact opening 74 exposes an inward part of the base region 40, inward parts of the plurality of source regions 41, and inward parts of the plurality of base contact regions 43. In this embodiment, the contact opening 74 is formed in the shape of a strip extending along the first direction X. An outer end part of the gate insulation film 72 is connected to the insulation film 70 (an inner end part of the first insulation film 70A).

In this embodiment, the gate electrode 73 contains conductive polysilicon. The gate electrode 73 is formed on the gate insulation film 72, and faces the channel region 42 across the gate insulation film 72. The gate electrode 73 has a lead portion 75 led out of it from over the gate insulation film 72 to over the insulation film 70 (first insulation film 70A). The lead portion 75 of the gate electrode 73 faces the drift region 51 across the insulation film 70 (first insulation film 70A).

Specifically, as seen in a plan view, the gate electrode 73 has an inner end part and an outer end part and is formed in a ring shape surrounding the base region 40. The inner end part of the gate electrode 73 along with the inner end part of the gate insulation film 72 defines the contact opening 74.

An outer end part of the gate electrode 73 is formed by the lead portion 75, and is formed on the insulation film 70, at an interval from an inner end part of the well region 50 inward as seen in a plan view. In this embodiment, an outer end part of the gate electrode 73 is located, as seen in a plan view, in a region between the base region 40 and the well region 50. An outer end part of the gate electrode 73 is formed, as seen in a plan view, in a quadrangular shape (specifically, a rectangular shape extending along the first direction X). An outer end part of the gate electrode 73 can have any planar shape, and can be formed in an oval shape.

The plurality of source regions 41 and the plurality of base contact regions 43 can each be formed in a self-aligning manner with respect to the gate electrode 73. That is, the plurality of source regions 41 and the plurality of base contact regions 43 can each be formed by introducing an n-type dopant and a p-type dopant through an ion injection mask that exposes at least an inner end part of the gate electrode 73. In that case, a loop array of n-type regions and p-type regions corresponding to the loop array of the plurality of source regions 41 and the plurality of base contact regions 43 is formed at least in an inner end part of the gate electrode 73.

The semiconductor device 1 includes an interlayer insulation film 80 formed on top of the first main face 21. The interlayer insulation film 80 is formed on the insulation film 70 and coats the entire diode region 28. The interlayer insulation film 80 coats the parts exposed through the insulation film 70 of the region separation structure 30 (column region 31), the plurality of base regions 40, the plurality of source regions 41, the plurality of base contact regions 43, the plurality of well regions 50, the plurality of drain regions 54, the plurality of outer drain regions 55, the plurality of dopant regions 56, the guard region 60, and the CS region 65.

The semiconductor device 1 includes one or more (in this embodiment, one) region separation connection electrode 81, a plurality of source connection electrodes 82, a plurality of drain connection electrodes 83, one or more (in this embodiment, one) guard connection electrode 84, and a plurality of gate connection electrodes 86.

The region separation connection electrode 81 penetrates the interlayer insulation film 80 and is electrically connected to the region separation structure 30 (column contact region 34). The region separation connection electrode 81 is fixed at a reference potential (e.g., ground potential). The region separation connection electrode 81 can be formed, as seen in a plan view, in the shape of a strip (specifically, in a ring shape) extending along the region separation structure 30.

The plurality of source connection electrodes 82 penetrate the interlayer insulation film 80 and are electrically connected to the corresponding base regions 40, to the corresponding ones of the plurality of source regions 41, and to the corresponding ones of the plurality of base contact regions 43. The plurality of source connection electrodes 82 are fixed at a gate potential. That is, the plurality of source connection electrodes 82 are fixed at the same potential as the gate electrode 73.

The plurality of source connection electrodes 82 are each formed, in the corresponding contact opening 74, in the shape of a strip that crosses the plurality of source regions 41 and the plurality of base contact regions 43 along first direction X. Opposite end parts of the plurality of source connection electrodes 82 are electrically connected to opposite end parts of the corresponding base regions 40. Thus, the base regions 40, the source regions 41, and the base contact regions 43 are fixed at the same potential (gate potential).

The plurality of drain connection electrodes 83 penetrate the interlayer insulation film 80 and are electrically connected to the corresponding ones of the plurality of drain regions 54 and the corresponding ones of the plurality of dopant regions 56. The plurality of drain connection electrodes 83 are fixed at a drain potential. The plurality of drain connection electrodes 83 are each formed in the shape of a strip that crosses the plurality of drain regions 54 and the plurality of dopant regions 56 along the example.

Opposite ends of the plurality of drain connection electrodes 83 are connected respectively to the drain regions 54 at opposite ends. That is, the plurality of drain connection electrodes 83 are electrically connected to the plurality of outer drain regions 55 via the drain regions 54 at opposite ends. Thus, the well region 50, the drain regions 54, the outer drain regions 55, and the dopant regions 56 are fixed a the same potential (drain potential).

The guard connection electrode 84 penetrates the interlayer insulation film 80 and is electrically connected to the guard region 60. The guard connection electrode 84 is fixed at the same potential (drain potential) as the plurality of drain connection electrodes 83. That is, the guard region 60 is fixed at the same potential as the drain regions 54 and the like. The guard connection electrode 84 can be formed, as seen in a plan view, in the shape of a strip (specifically, in a ring shape) extending along the guard region 60. A plurality of guard connection electrodes 84 can be formed, as seen in a plan view, at intervals along the guard region 60.

The plurality of gate connection electrodes 86 penetrate the interlayer insulation film 80 and are electrically connected to the corresponding gate electrodes 73. Specifically, the plurality of gate connection electrodes 86 are electrically connected to, at whatever positions on, the lead portions 75 of the corresponding gate electrodes 73. In this embodiment, the plurality of gate connection electrodes 86 are electrically connected respectively to opposite end parts of the plurality of gate electrodes 73 along the first direction X. In FIGS. 7 and 8, a gate connection electrode 86 is illustrated for convenience' sake to show how it is connected. The plurality of gate connection electrodes 86 are fixed at the gate potential. That is, the gate electrode 73 is fixed at the same potential as the base region 40, the source regions 41, the base contact regions 43, and the like.

Referring to FIG. 7, the first reverse current prevention diode 13 includes a diode structure 90 of an EIS (electrode-insulator-semiconductor) type. Specifically, the diode structure 90 includes a p-type base region 40, an n-type source region 41, a p-type base contact region 43, an n-type well region 50, an n-type drain region 54, and a gate structure 71.

Referring to FIG. 8, the first reverse current prevention diode 13 includes a thyristor structure 91 electrically connected to the diode structure 90. Specifically, the thyristor structure 91 includes a p-type dopant region 56, an n-type semiconductor layer 25, a p-type base region 40, and an n-type source region 41 that are formed in this order along the first main face 21 of the semiconductor layer 25.

More specifically, the thyristor structure 91 includes a first transistor structure 92 of a pnp type (first polarity type) at the well region 50 side and a second transistor structure 93 of an npn type (second polarity type) at the base region 40 side. The first transistor structure 92 includes a p-type dopant region 56, an n-type semiconductor layer 25, and a p-type base region 40 that are formed in this order along the first main face 21 of the semiconductor layer 25. The second transistor structure 93 includes an n-type source region 41, a p-type base region 40, and an n-type semiconductor layer 25 that are formed in this order along the first main face 21 of the semiconductor layer 25.

If a forward voltage VF across the diode structure 90 is applied to the source connection electrodes 82 (gate electrode 73) and the drain connection electrode 83, the diode structure 90 is on and the thyristor structure 91 is off. The thyristor structure 91 being on results from the drain region 54 and the dopant region 56 being fixed at the same potential. Thus the diode structure 90 conducts and a forward current IF passes through the diode structure 90. The forward voltage VF also passes through the first transistor structure 92, which is electrically connected to the diode structure 90.

By contrast, if a reverse voltage VR across the diode structure 90 is applied to the source connection electrodes 82 (gate electrode 73) and the drain connection electrode 83, the diode structure 90 is off and the thyristor structure 91 is on. Thus the thyristor structure 91 conducts and a reverse current IR passes through the thyristor structure 91.

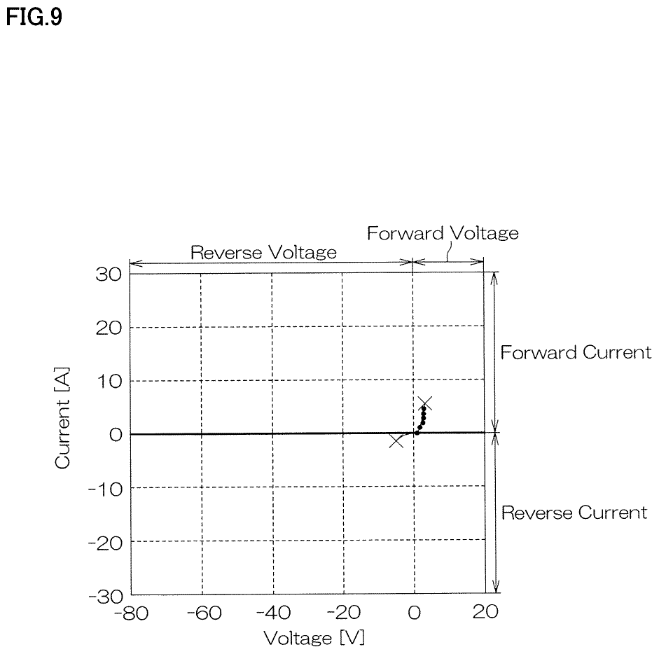

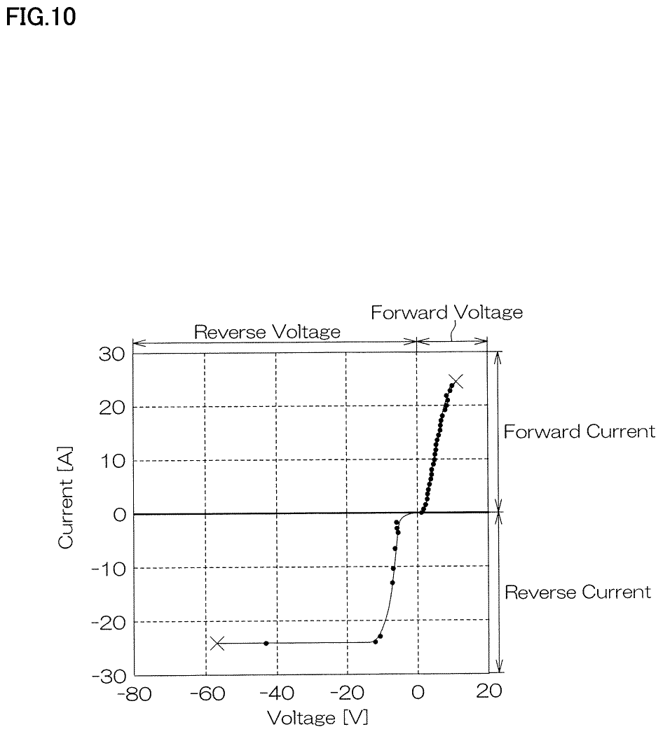

FIG. 9 is a graph showing the current-voltage response of a reverse current prevention diode according to a comparative example. FIG. 10 is a graph showing the current-voltage response of the first reverse current prevention diode 13 according to this embodiment. The current-voltage responses shown in FIGS. 9 and 10 are measurement results obtained by the well-known TLP (transmission line pulse) method.

In FIGS. 9 and 10, the vertical axis represents current [A] and the horizontal axis represents voltage [V]. A positive current is a forward current IF and a negative current is a reverse current IR. A positive voltage is a forward voltage VF and a negative voltage is a reverse voltage VR. The reverse current prevention diode of the comparative example has no dopant regions 56. That is, the reverse current prevention diode of the comparative example only has a diode structure 90 and has no thyristor structure 91.

With the reverse current prevention diode of the comparative example, the forward current IF that causes electrostatic breakdown is approximately +5 A, and the reverse current IR that causes electrostatic breakdown is approximately −0.5 A. By contrast, with the first reverse current prevention diode 13 of this embodiment, the forward current IF that causes electrostatic breakdown is approximately +25 A, and the reverse current IR that causes electrostatic breakdown is approximately −24 A. As compared with the reverse current prevention diode of the comparative example, the first reverse current prevention diode 13 of this embodiment offers an improved electrostatic surge tolerance in both the forward and reverse directions.

Unlike the reverse current prevention diode of the comparative example, when a forward overvoltage ascribable to static electricity or the like is applied to it, the first reverse current prevention diode 13 of this embodiment can cope with a forward overcurrent with the diode structure 90 and the first transistor structure 92.

On the other hand, when a reverse overvoltage ascribable to static electricity or the like is applied to it, the first reverse current prevention diode 13 of this embodiment can cope with a reverse overcurrent with the thyristor structure 91. As a result, as compared with the reverse current prevention diode of the comparative example, the first reverse current prevention diode 13 of this embodiment provides an improved electrostatic surge tolerance.

Thus, with the semiconductor device 1, it is possible to obtain an improved electrostatic surge tolerance. In particular, in a structure incorporating the thyristor structure 91, the improved electrostatic surge tolerance against the forward voltage (forward current IF) achieved by the operation of the first transistor structure 92 is a distinctive effect that cannot be achieved with common thyristor devices that are used as a protection device against a reverse voltage VR.

Moreover, in the semiconductor device 1, the dopant regions 56 are formed in a superficial part of the well region 50, at an interval from edge parts of the well region 50 inward. With this structure, with respect to the lateral direction parallel to the first main face 21, parts of the well region 50 are interposed in regions between the dopant regions 56 and the semiconductor layer 25, and those parts of the well region 50 reduce the base resistance of the first transistor structure 92. This permits the thyristor structure 91 to operate properly.

For example, in a case where in a superficial part of the well region 50 the drain regions 54 are formed in regions between the dopant regions 56 and the semiconductor layer 25, the base of the first transistor structure 92 is short-circuited to the emitter of the first transistor structure 92 via the drain regions 54, which have a relatively low resistance. This destabilizes the operation of the thyristor structure 91.

To cope with that, in the semiconductor device 1, edge parts of the dopant regions 56 facing the base region 40 are formed more inward of the well region 50 than edge parts of the drain regions 54 facing the base region 40. With this structure, the base and the emitter of the first transistor structure 92 can be properly prevented from being short-circuited via the drain regions 54. This permits the thyristor structure 91 to operate more properly. Moreover, with this structure, if an overvoltage is applied between the drain region 54 and the source region 41, a punch through between the drain region 54 and the source region 41 can be prevented. It is thus possible to suppress a drop in the punch through breakdown voltage.

Moreover, in the semiconductor device 1, the dopant region 56 faces the drain region 54 in a direction orthogonal to the direction in which the base region 40 and the base region 40 face each other. With this structure, the thyristor structure 91 can be formed on a line connecting between the base region 40 and the dopant region 56. It is thus possible to properly prevent the operation of the thyristor structure 91 from being impaired by the drain region 54.

Moreover, the semiconductor device 1 includes the p-type guard region 60 that is formed in a superficial part of the first main face 21, in a region of the column region 31 and the well region 50. The guard region 60 is fixed at the same potential as the drain region 54 and the like. Specifically, the semiconductor device 1 includes the drain connection electrode 83 that is connected to the drain region 54 and the like on the first main face 21 and the guard connection electrode 84 that is electrically connected to the guard region 60 on the first main face 21 and that is fixed at the same potential as the drain connection electrode 83.

In the diode region 28, in a region between the column region 31 and the base region 40 is formed a first parasitic transistor of a pnp type (first polarity type) that includes a p-type base region 40, an n-type semiconductor layer 25, and a p-type column region 31. If a forward voltage VF across the diode structure 90 is applied to the source connection electrodes 82 (gate electrode 73) and the drain connection electrode 83, a leak current passes through the column region 31 via the first parasitic transistor.

To cope with that, the semiconductor device 1 has the guard region 60 formed between the column region 31 and the well region 50. With this structure, in the diode region 28, in a region between the column region 31 and the base region 40 is formed a second parasitic transistor of a pnp type (first polarity type) that includes a p-type base region 40, an n-type semiconductor layer 25, and a p-type guard region 60.

Thus, if a forward voltage VF across the diode structure 90 is applied, a leak current can be passed into the guard connection electrode 84 via the second parasitic transistor. This makes it possible to reduce leak current without being impaired by the thyristor structure 91. Reducing leak current is effective in improving the electrical characteristics of the diode region 28, and is effective also in suppressing variation of the electrical characteristics of other functional device regions 27 ascribable to the leak current.

The present disclosure allows other embodiments.

The embodiment described above deals with an example where the insulation film 70 is a field oxidation film. Instead, the insulation film 70 can be embedded in a trench. In that case, the trench and the insulation film 70 can constitute an STI (shallow trench isolation) structure.

While the embodiment described above deals with an example where the “first conductivity type” is the “p type” and the “second conductivity type” is the “n type”, instead the “first conductivity type” can be the “n type” and the “second conductivity type” can be the “p type”. In that case, a specific configuration can be derived by replacing “n-type regions” with “p-type regions” and “p-type regions” with “n-type regions” in the description given above and in the accompanying drawings. While the embodiment described above deals with an example where, for the sake of clarity of the development of description, the “p type” is referred to as the “first conductivity type” and the “n type” is referred to as the “second conductivity type”, instead the “p type” can be referred to as the “second conductivity type” and the “n type” can be referred to as the “first conductivity type”.

While the embodiment described above deals with an example where the first reverse current prevention diode 13 (second reverse current prevention diode 17) is incorporated in a circuit of a CAN, instead the first reverse current prevention diode 13 (second reverse current prevention diode 17) can be incorporated in a circuit of any of various applications other than a CAN. For example, the first reverse current prevention diode 13 (second reverse current prevention diode 17) can be incorporated in a circuit of a vehicle onboard network such as LIN (local interconnect network) or FlexRay, a circuit of a vehicle onboard switching IC, a circuit of a DC/DC converter, or the like. The first reverse current prevention diode 13 (second reverse current prevention diode 17) can be incorporated in a circuit of any application other than vehicle onboard applications.

Some examples of the features that can be extracted from the present description and the accompanying drawings will be discussed below. An EIS diode structure has a structural feature that it has a low electrostatic surge tolerance. Electrostatic surge tolerance is also called ESD (electrostatic discharge) tolerance. Configurations [A1] to [A17] presented below provide semiconductor devices with an EIS diode structure that offer an improved electrostatic surge tolerance.

[A1] A semiconductor device including: a semiconductor layer of a first conductivity type having a main face and including a device region; a base region of a second conductivity type formed in the device region, in a superficial part of the main face; a source region of the first conductivity type formed in a superficial part of the base region at a interval inward from an edge part of the base region, the source region demarcating a channel region from the base region; a base contact region of the second conductivity type formed in a superficial part of the base region, in a region different from the source region, the base contact region having a dopant concentration more than the dopant concentration in the base region; a well region of the first conductivity type formed in the device region, in a superficial part of the main face at an interval from the base region, the well region demarcating a drift region from the base region; a drain region of the first conductivity type formed in a superficial part of the well region; a dopant region of the second conductivity type formed in a superficial part of the well region and electrically connected to the drain region; a gate structure having a gate insulation film coating the channel region on the main face and a gate electrode on the gate insulation film, the gate electrode facing the channel region and electrically connected to the source region and to the base contact region.

This semiconductor device includes an EIS diode structure in the device region. Specifically, the diode structure includes the base region, the source region, the base contact region, the well region, the drain region, and the gate structure. This semiconductor device also includes a thyristor structure electrically connected to the diode structure in the device region. Specifically, the thyristor structure includes the dopant region (second conductivity type), the semiconductor layer (first conductivity type), the base region (second conductivity type), and the source region (first conductivity type) formed in this order along the main face of the semiconductor layer.

More specifically, the thyristor structure includes a first transistor structure of the first polarity type at the well region side and a second transistor structure of the second polarity type at the base region side. The first transistor structure includes the dopant region (second conductivity type), the semiconductor layer (first conductivity type), and the base region (second conductivity type) formed in this order along the main face of the semiconductor layer. The second transistor structure includes the source region (first conductivity type), the base region (second conductivity type), and the semiconductor layer (first conductivity type) formed in this order along the main face of the semiconductor layer.

When a forward voltage is applied to the diode structure, the diode structure is on and the thyristor structure is off. The thyristor structure is off as a result of the drain region and the dopant region being fixed at the same potential. Thus the diode structure conducts and a forward current passes through the diode structure. This forward voltage also passes through the first transistor structure electrically connected to the diode structure. Accordingly, if a forward overvoltage ascribable to static electricity or the like is applied to the diode structure, a forward overcurrent can be coped with by the diode structure and the first transistor structure.

On the other hand, if a reverse voltage is applied to the diode structure, the diode structure is off and the thyristor structure is on. Thus the thyristor structure conducts and a reverse current passes through the thyristor structure. Accordingly, if a reverse overvoltage ascribable to static electricity or the like is applied to the diode structure, a reverse overcurrent can be coped with by the thyristor structure. Thus this semiconductor device provides an improved electrostatic surge tolerance.

[A2] In the semiconductor device of configuration A1, the dopant region can be formed at an interval inward from an edge part of the well region.

[A3] In the semiconductor device of configuration A1 or A2, the dopant region can be connected to the drain region in a direction orthogonal to the direction in which the base region and the well region face each other.

[A4] In the semiconductor device of any of configurations A1 to A3, as the dopant region, a plurality of dopant regions can be formed so as to sandwich, as the drain region, one drain region at a place.

[A5] In the semiconductor device of any of configurations A1 to A4, as the dopant region, a plurality of dopant regions can be formed at intervals.

[A6] In the semiconductor device of any of configurations A1 to A5, the base region can be formed, as seen in a plan view, in the shape of a strip extending along one direction, and the dopant region can be formed in the well region, in a region facing a longer side of the base region,

[A7] In the semiconductor device of any of configurations A1 to A6, the well region can be formed, as seen in a plan view, in a ring shape surrounding the base region, and the gate electrode can be formed, as seen in a plan view, in a region between the base region and the well region, in a ring shape surrounding the base region.

[A8] The semiconductor device of any of configurations A1 to A7 can further include a region separation structure that electrically separates the device region from other regions.

[A9] In the semiconductor device of configuration A8, the region separation structure can be a column region of the second conductivity type formed in the semiconductor layer.

[A10] The semiconductor device of configuration A9 can further include a guard region formed in a superficial part of the main face, in a region between the well region and the column region, the guard region being electrically connected to the drain region.

[A11] In the semiconductor device of any of configurations A1 to A10, the base contact region can be formed in a superficial part of the base region at an interval inward from an edge part of the base region, the base contact region being electrically connected to the source region.

[A12] The semiconductor device of any of configurations A1 to A11 can further include an insulation film coating the drift region on the main face, and the gate insulation film can have a thickness less than the thickness of the insulation film and can be continuous with the insulation film.

[A13] In the semiconductor device of configuration A12, the gate electrode can include a lead portion that is led out of it from over the gate insulation film to over the insulation film and that faces the drift region across the insulation film.

[A14] The semiconductor device of any of configurations A1 to A13 can further include a semiconductor substrate of the second conductivity type, and the semiconductor layer can be stacked on top of the semiconductor substrate.

[A15] The semiconductor device of configuration A14 can further include an embedded region of the first conductivity type formed in the device region, across the boundary between the semiconductor substrate and the semiconductor layer, and the base region and the well region can face the embedded region across part of the semiconductor layer.

[A16] The semiconductor device of configuration A15 can further include a channel stop region of the first conductivity type formed in the semiconductor layer, in the device region along the peripheral edge of the device region.

[A17] In the semiconductor device of configuration A16, the channel stop region can extend in the shape of a wall toward the embedded region and can be electrically connected to the embedded region.

This application corresponds to the patent application No. 2019-217069 filed with the Japan Patent Office on Nov. 29, 2019, of which the entire disclosure is hereby incorporated herein. While an embodiment of the present disclosure has so far been described in detail, it merely presents specific examples in illustration of the technical ideas of the present disclosure and those examples are not in any way meant to limit the present disclosure, of which the scope is defined by the claims appended herewith.

### Second Embodiment

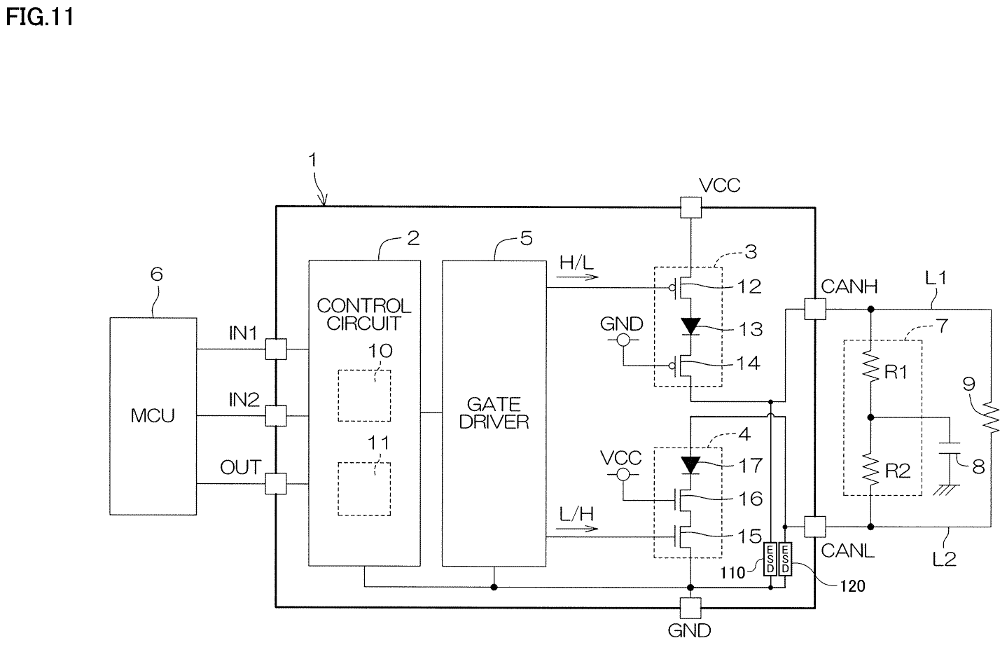

FIG. 11 is a circuit diagram showing the electrical structure of a principal portion of a semiconductor device 1 according to a second embodiment of the present disclosure. The semiconductor device 1 of this embodiment is based on the first embodiment (FIG. 1) described previously, and further includes a first electrostatic protection circuit 110 and a second electrostatic protection circuit 120.

The first electrostatic protection circuit 110 is connected between the high-side terminal CANH (corresponding to a first signal terminal that functions as a high-side bus input/output terminal) and the ground terminal GND (corresponding to a ground terminal), and protects the semiconductor device 1 from positive and negative electrostatic surges that can be applied to the high-side terminal CANH.

The second electrostatic protection circuit 120 is connected between the low-side terminal CANL (corresponding to a second signal terminal that functions as a low-side bus input/output terminal) and the ground terminal GND (corresponding to a ground terminal), and protects the semiconductor device 1 from positive and negative electrostatic surges that can be applied to the low-side terminal CANL.

Though not specifically mentioned in connection with the first embodiment (FIG. 1) described previously, in practice, as shown in the diagram, a CAN transceiver IC has the first and second electrostatic protection circuits 110 and 120 provided between the high-side and low-side terminals CANH and CANL, respectively, and the ground terminal GND.

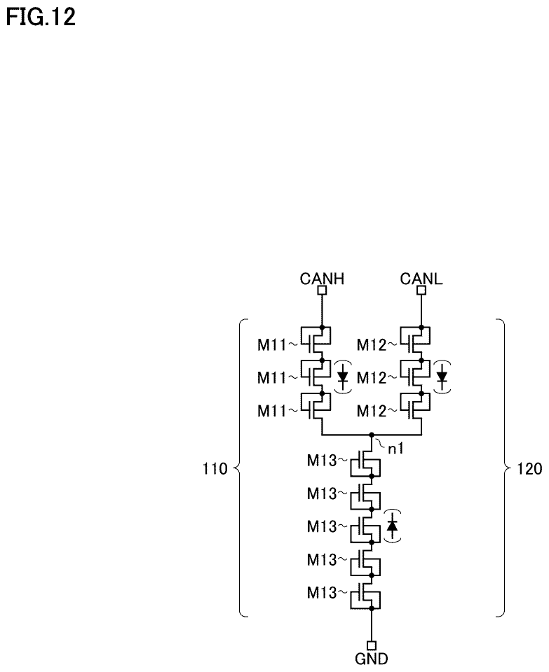

FIG. 12 is a diagram showing one example of the first and second electrostatic protection circuits 110 and 120 according to the second embodiment.

In the semiconductor device 1 of this embodiment, the first and second electrostatic protection circuits 110 and 120 include three first electrostatic protection diodes M11, three second electrostatic protection diodes M12, and five third electrostatic protection diodes M13.

The three first electrostatic protection diodes M11 are connected between the high-side terminal CANH and an internal node n1, in series with each other with such a polarity (corresponding to a first polarity) that the anodes point to the high-side terminal CANH and the cathodes point to the internal node n1.

Likewise, the three second electrostatic protection diodes M12 are connected between the low-side terminal CANL and the internal node n1, in series with each other with such a polarity (corresponding to the first polarity) that the anodes point to the low-side terminal CANL and the cathodes point to the internal node n1.

On the other hand, the five third electrostatic protection diodes M13 are connected between the internal node n1 and the ground terminal GND, in series with each other with such a polarity (corresponding to a second polarity reverse to the first polarity) that the cathodes point to the internal node n1 and the anodes point to the ground terminal GND.

The first electrostatic protection circuit 110 is constituted by the three first electrostatic protection diodes M11 and the five third electrostatic protection diodes M13. On the other hand, the second electrostatic protection circuit 120 is constituted by the three second electrostatic protection diodes M12 and the five third electrostatic protection diodes M13. Thus the five third electrostatic protection diodes M13 are shared between the first and second electrostatic protection circuits 110 and 120.

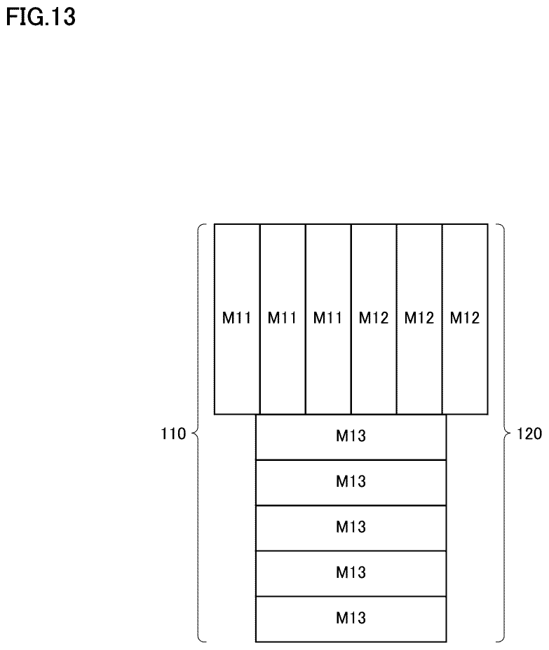

FIG. 13 is a diagram showing one example of the element layout (i.e., an example of the arrangement of the first, second, and third electrostatic protection diodes M1, M12, and M13) according to the second embodiment.

As shown in the diagram, as seen in a plan view of the semiconductor device 1, the first and second electrostatic protection diodes M11 and M12 are each formed in a rectangular shape of which the longer sides run along the up/down direction on the plane of the diagram and of which the shorter sides run along the left/right direction on the plane of the diagram. The first and second electrostatic protection diodes M11 and M12 are arrayed in a row along the left/right direction on the plane of the diagram. In terms of what is shown in the diagram, the three first electrostatic protection diodes M11 and the three second electrostatic protection diodes M12 are arrayed one contiguous with the next from left to right on the plane of the diagram.

On the other hand the third electrostatic protection diodes M13 are each formed, as seen in a plan view of the semiconductor device 1, in a rectangular shape of which the longer sides run along the left/right direction on the plane of the diagram and of which the shorter sides run along the up/down direction on the plane of the diagram. The third electrostatic protection diodes M13 are arrayed in a row along the up/down direction on the plane of the diagram. Moreover, in terms of what is shown in the diagram, the upper side of the third electrostatic protection diode M13 located farthest up on the plane of the diagram is disposed to be contiguous with the bottom sides of at least some of the first and second electrostatic protection diodes M11 and M12.

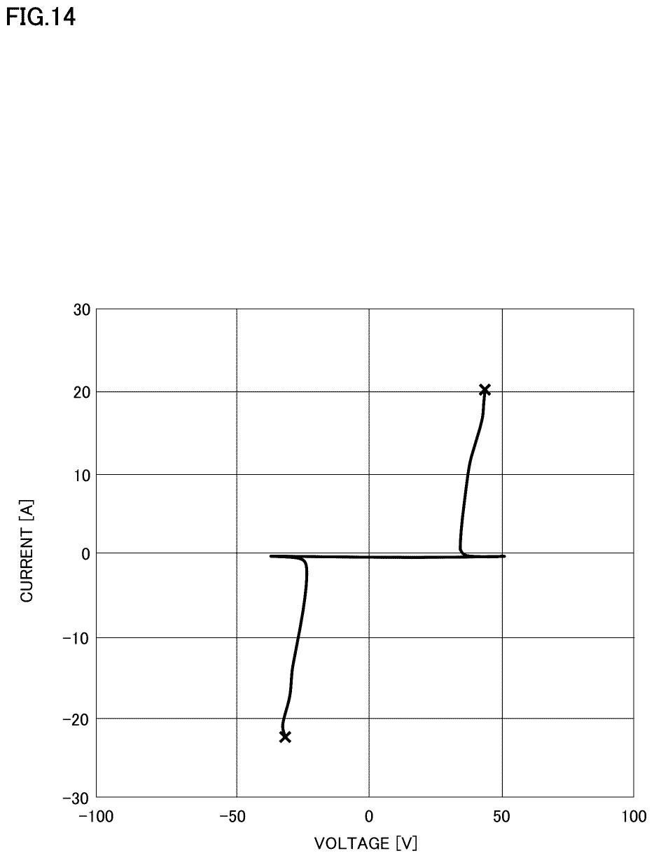

FIG. 14 is a diagram showing the current-voltage response of the first and second electrostatic protection circuits 110 and 120 according to the second embodiment. In the diagram, the vertical axis represents current [A] and the horizontal axis represents voltage [V]. The current-voltage responses shown in the diagram are measurement results obtained by the well-known TLP (transmission line pulse) method.

As shown in the diagram, with the semiconductor device 1 according to the second embodiment, if an electrostatic surge exceeding the relevant one of the rated voltages (e.g., −27 V to +40 V) of the high-side and low-side terminals CANH and CANL is applied, it is coped with by a current passing through the first and second electrostatic protection circuits 110 and 120. It is thus possible to secure safety with the semiconductor device 1.

Moreover, with the semiconductor device 1 according to the second embodiment, as mentioned above, the third electrostatic protection diodes M13 are shared between the first and second electrostatic protection circuits 110 and 120. This makes it possible to reduce the number of third electrostatic protection diodes M13 by half as compared with a configuration where the third electrostatic protection diodes M13 are provided for each of the first and second electrostatic protection circuits 110 and 120. It is thus possible to reduce the area of the semiconductor device 1.

Incidentally, the semiconductor device 1 of the second embodiment employs low-withstand-voltage NMOS transistors as the first, second, and third electrostatic protection diodes M11, M12, and M13. This is because low-withstand-voltage NMOS transistors (with a DC withstand voltage of several volts) are more resistant to application of instantaneous static electricity than high-withstand-voltage NMOS transistors (with a DC withstand voltage of several tens of volts).

However, a low-withstand-voltage NMOS transistor cannot by oneself withstand application of the rated DC voltages (e.g., −27 V to +40 V) defined for the high-side and low-side terminals CANH and CANL respectively. To cope with that, in the semiconductor device 1 of the second embodiment, a boosted DC withstand voltage is achieved by vertically stacking a plurality of low-withstand-voltage NMOS transistors, and this may discourage further area-saving (see FIGS. 12 and 13 referred to previously).

In view of what has been studied above, presented below will be, as a third embodiment, a novel configuration that achieves a high DC withstand voltage and a high EDS tolerance combined with area saving.

### Third Embodiment

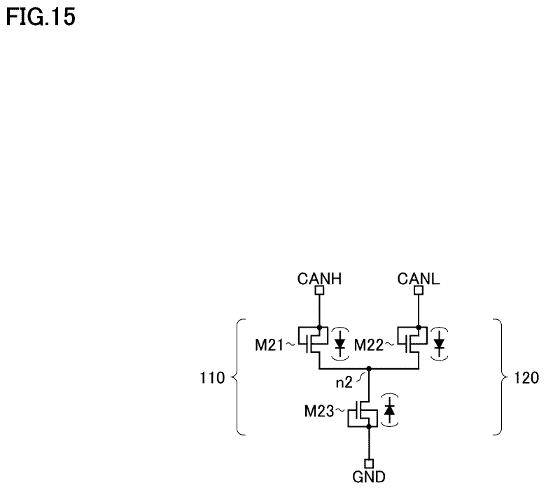

FIG. 15 is a diagram showing one example of the first and second electrostatic protection circuits 110 and 120 according to a third embodiment.

In the semiconductor device 1 of this embodiment, the first and second electrostatic protection circuits 110 and 120 include a first electrostatic protection diode M21, a second electrostatic protection diode M22, and a third electrostatic protection diode M23.

The first electrostatic protection diode M21 is connected between the high-side terminal CANH and an internal node n2, with such a polarity (corresponding to a first polarity) that the anode points to the high-side terminal CANH and the cathode points to the internal node n2.

Likewise, the second electrostatic protection diode M22 is connected between the low-side terminal CANL and the internal node n2, with such a polarity (corresponding to a first polarity) that the anode points to the low-side terminal CANL and the cathode points to the internal node n2.

On the other hand, the third electrostatic protection diode M23 is connected between the internal node n2 and the ground terminal GND, with such a polarity (a second polarity reverse to the first polarity) that the cathode points to the internal node n2 and the anode points to the ground terminal GND.

In terms of what is shown in the diagram, the anode of the first electrostatic protection diode M21 is connected to the high-side terminal CANH. The anode of the second electrostatic protection diode M22 is connected to the low-side terminal CANL. The anode of the third electrostatic protection diode M23 is connected to the ground terminal GND. The cathodes of the first, second, and third electrostatic protection diodes M21, M22, and M23 are connected together at the internal node n2.

The first electrostatic protection circuit 110 is constituted by the first and third electrostatic protection diodes M21 and M23. On the other hand, the second electrostatic protection circuit 110 is constituted by the second and third electrostatic protection diodes M22 and M23. Thus the third electrostatic protection diode M23 is shared between the first and second electrostatic protection circuits 110 and 120.

In this respect, the configuration here is no different from that of the second embodiment (FIG. 12) described previously. This makes it possible to reduce the number of third electrostatic protection diodes M23 by half as compared with a configuration where the third electrostatic protection diode M23 is provided for each of the first and second electrostatic protection circuits 110 and 120. It is thus possible to reduce the area of the semiconductor device 1.

What is particular about the semiconductor device 1 of the third embodiment is that it employs, as the first, second, and third electrostatic protection diodes M21, M22, and M23, not low-withstand-voltage NMOS transistors but lateral NDMOS transistors thyristorized by having a p-type dopant region formed in their drain.

A thyristorized lateral NDMOS transistor has an element structure (see FIGS. 7 and 8) similar to that of the first and second reverse current prevention diodes 13 and 17 described previously. While no overlapping description will be repeated, a brief description follows with reference to FIGS. 7 and 8. A thyristorized lateral NDMOS transistor includes a thyristor structure 91 electrically connected to a diode structure 90.

Specifically, a semiconductor device 1 (in particular, a thyristorized lateral NDMOS transistor) includes: an n-type semiconductor layer 25 having a first main face 21 and including a device region 26; a p-type base region 40 formed in the device region 26, in a superficial part of the first main face 21; an n-type source region 41 formed in a superficial part of the base region 40 at an interval inward from an edge part of the base region 40, the source region 41 demarcating a channel region 42 from the semiconductor layer 25; a p-type base contact region 43 formed in a superficial part of the base region 40, in a region different from the source region 41, the base contact region 43 having a dopant concentration higher than the dopant concentration in the base region 40; an n-type well region 50 formed in the device region 26, in a superficial part of the first main face 21 at an interval from the base region 40, the well region 50 demarcating a drift region from the base region 40; an n-type drain region 54 formed in a superficial part of the well region 50; a p-type dopant region 56 formed in a superficial part of the well region 50 and electrically connected to the drain region 54; and a gate structure 71 including a gate insulation film 72 coating the channel region 42 on the first main face 21 and a gate electrode 73 on the gate insulation film 72, the gate electrode 73 facing the channel region 42 and electrically connected to the source region 41 and to the base contact region 43.

The thyristorized lateral NDMOS transistor not only exhibits a high electrostatic surge tolerance but has a very high DC withstand voltage (e.g., −40 V to +40 V). Thus it can by itself withstand application of the rated DC voltages (e.g., −27 V to +40 V) defined for the high-side and low-side terminals CANH and CANL respectively. Accordingly, unlike the second embodiment described previously, the semiconductor device 1 of the third embodiment does not require boosting a DC withstand voltage by vertically stacking a plurality of low-withstand-voltage NMOS transistors, and this helps achieve further area saving.

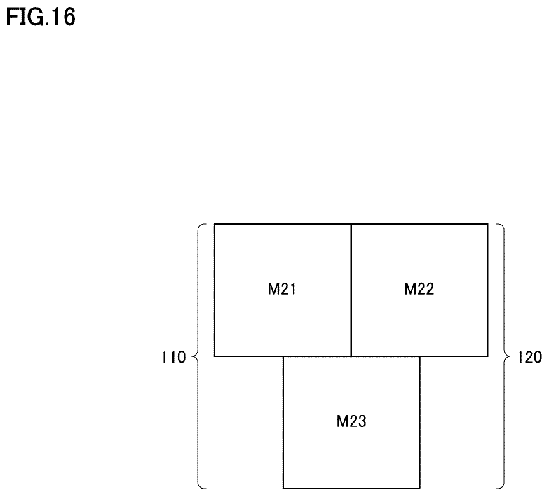

FIG. 16 is a diagram showing one example of the element layout (an example of the arrangement of the first, second, and third electrostatic protection diodes M21, M22, and M23) according to the third embodiment.

As shown in the diagram, the first, second, and third electrostatic protection diodes M21, M22, and M23 are each formed, as seen in a plan view of the semiconductor device 1, in a rectangular (generally square) shape.

The first and second electrostatic protection diodes M21 and M22 are disposed to be contiguous with each other along the left/right direction on the plane of the diagram, so as to share one side (in the diagram, the right side of the first electrostatic protection diode and the left side of the second edge part diode).

On the other hand, the third electrostatic protection diode M23 is disposed to be contiguous with the first and second electrostatic protection diodes M21 and M22 along the up/down direction on the plane of the diagram. In terms of what is shown in the diagram, the third electrostatic protection diode M23 is disposed such that its top side overlaps evenly with the bottom sides of the first and second electrostatic protection diodes M21 and M22. That is, the side shared between the first and second electrostatic protection diodes M21 and M22 corresponds to a line that is normal to, and divides into two equal parts, the top side of the third electrostatic protection diode M23.

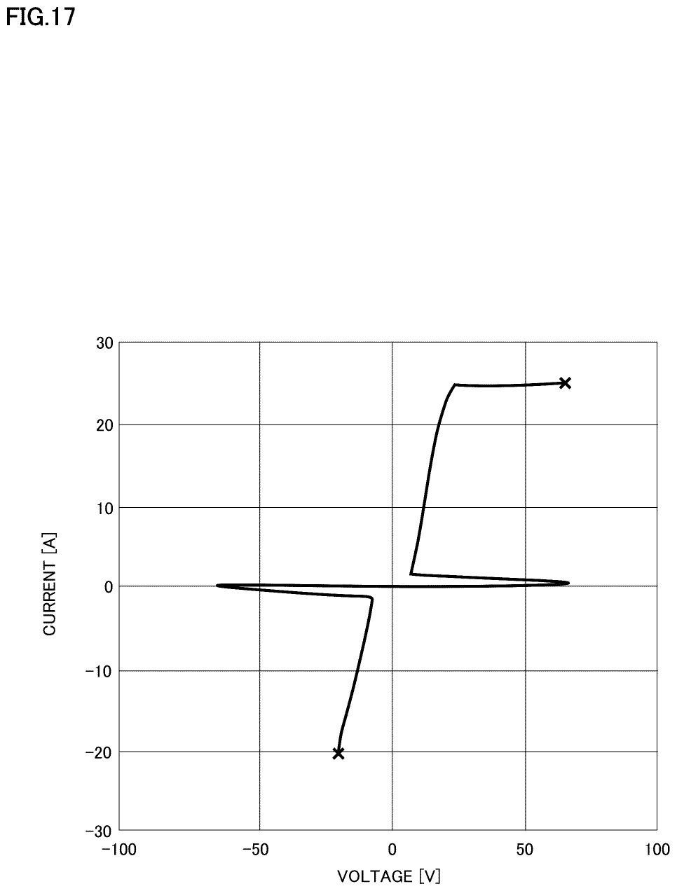

FIG. 17 is a diagram showing the current-voltage response of the first and second electrostatic protection circuits 110 and 120 according to the third embodiment. In the diagram, as in FIG. 14 referred to previously, the vertical axis represents current [A] and the horizontal axis represents voltage [V]. The current-voltage responses shown in the diagram are measured by the well-known TLP (transmission line pulse) method.

As shown in the diagram, the semiconductor device 1 of the third embodiment withstands application of a high DC voltage (e.g., −40 V to +40 V) with no stacking of a plurality of transistor elements. It is thus possible to achieve a high DC withstand voltage and a high ESD tolerance combined with space saving.

### Fourth Embodiment

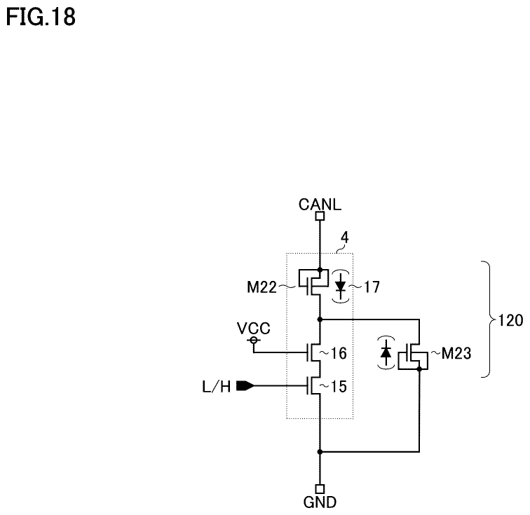

FIG. 18 is a diagram showing one example of the second electrostatic protection circuit 120 (and circuits peripheral to it) according to a fourth embodiment.

As shown in the diagram, in the low-side output circuit 4, the second electrostatic protection diode M22 described previously can be shared as the second reverse current prevention diode 17 for preventing a reverse current from the ground terminal GND to the low-side terminal CANL. In that case, the third electrostatic protection diode M23 belonging to the second electrostatic protection circuit 120 is connected in parallel with the second driving transistor 15 and the second protection transistor 16 included in the low-side output circuit 4.

With this configuration, it is possible to reduce the number of transistor elements, and this helps achieve further area saving in the semiconductor device 1.

### Overview

To follow is an overview of the various embodiments described herein.

For example, according to one aspect of what is disclosed herein, a semiconductor device includes, as an electrostatic protection diode, a lateral NDMOS transistor thyristorized by having a p-type dopant region formed in its drain. (A first configuration.)

For example, according to another aspect of what is disclosed herein, a semiconductor device includes: a first signal terminal; a second signal terminal; a ground terminal; and a first electrostatic protection diode, a second electrostatic protection diode, and a third electrostatic protection diode. The first, second, and third electrostatic protection diodes are each a lateral NDMOS transistor thyristorized by having a p-type dopant region formed in its drain. The anode of the first electrostatic protection diode is connected to the first signal terminal. The anode of the second electrostatic protection diode is connected to the second signal terminal. The anode of the third electrostatic protection diode is connected to the ground terminal. The cathodes of the first, second, and third electrostatic protection diodes are connected together. (A second configuration.)

In the semiconductor device of the second configuration described above, the first, second, and third electrostatic protection diodes can each be formed in a rectangular shape as seen in a plan view, he first and second electrostatic protection diodes can be disposed so as to share one side, and the third electrostatic protection diode can be disposed so as to be contiguous evenly with the first and second electrostatic protection diodes. (A third configuration.)

In the semiconductor device of the second or third configuration described above, the semiconductor device can be a CAN transceiver, the first signal terminal can be a high-side bus input/output terminal, and the second signal terminal can be a low-side bus input/output terminal. (A fourth configuration.)

The semiconductor device of the fourth configuration described above can further include: a high-side output circuit configured to switch between a conducting state and a cut-off state the path between the first signal terminal and a supply terminal; and a low-side output circuit configured to switch between a conducting state and a cut-off state the path between the second signal terminal and ground terminal. (A fifth configuration.)

In the semiconductor device of the fifth configuration described above, the high-side output circuit can include a first reverse current prevention diode configured to prevent a reverse current from the first signal terminal to the supply terminal. (A sixth configuration.)

In the semiconductor device of the fifth configuration described above, the low-side output circuit can include a second reverse current prevention diode configured to prevent a reverse current from the ground terminal to the second signal terminal. (A seventh configuration.)

In the semiconductor device of the fifth configuration described above, the low-side output circuit can share the second electrostatic protection diode as the second reverse current prevention diode configured to prevent a reverse current from the ground terminal to the second signal terminal. (An eighth configuration.)

In the semiconductor device of any of the first to eighth configurations described above, the lateral NDMOS transistor can include: a semiconductor layer of a first conductivity type having a main face and including a device region; a base region of a second conductivity type formed in the device region, in a superficial part of the main face; a source region of the first conductivity type formed in a superficial part of the base region at an interval inward from an edge part of the base region, the source region demarcating a channel region from the semiconductor layer; a base contact region of the second conductivity type formed in a superficial part of the base region, in a region different from the source region, the base contact region having a dopant concentration higher than the dopant concentration in the base region; a well region of the first conductivity type formed in the device region, in a superficial part of the main face at an interval from the base region, the well region demarcating a drift region from the base region; a drain region of the first conductivity type formed in a superficial part of the well region; a dopant region of the second conductivity type formed in a superficial part of the well region and electrically connected to the drain region; and a gate structure having: a gate insulation film coating the channel region on the main face; and a gate electrode on the gate insulation film, the gate electrode facing the channel region and electrically connected to the source region and to the base contact region. (A ninth configuration.)

For example, according to yet another aspect of what is disclosed herein, a semiconductor device includes: a first signal terminal; a second signal terminal; a ground terminal; at least one first electrostatic protection diode configured to be connected, with a first polarity, between the first signal terminal and an internal node; at least one second electrostatic protection diode configured to be connected, with the first polarity, between the second signal terminal and the internal node; and at least one third electrostatic protection diode configured to be connected, with a second polarity reverse to the first polarity, between the internal node and the ground terminal. (A tenth configuration.)

According to the disclosure herein, it is possible to provide a semiconductor device with an improved electrostatic surge tolerance.

### Further Modifications

The various technical features disclosed herein may be implemented in any manners other than as in the embodiments described above, and allow for many modifications without departure from the spirit of their technical ingenuity. That is, the embodiments described above should be taken to be in every aspect illustrative and not restrictive, and the technical scope of the present disclosure should be understood to be defined not by the description of the embodiments given above but by the appended claims and encompasses any modifications within a scope and sense equivalent to those claims.

1. A semiconductor device comprising, as an electrostatic protection diode, a lateral NDMOS transistor thyristorized by having a p-type dopant region formed in a drain thereof.

2. A semiconductor device comprising:
a first signal terminal;
a second signal terminal;
a ground terminal; and
a first electrostatic protection diode, a second electrostatic protection diode, and a third electrostatic protection diode,
wherein
the first, second, and third electrostatic protection diodes are each a lateral NDMOS transistor thyristorized by having a p-type dopant region formed in a drain thereof,
an anode of the first electrostatic protection diode is connected to the first signal terminal;
an anode of the second electrostatic protection diode is connected to the second signal terminal;
an anode of the third electrostatic protection diode is connected to the ground terminal; and
cathodes of the first, second, and third electrostatic protection diodes are connected together.

3. The semiconductor device according to claim 2, wherein
the first, second, and third electrostatic protection diodes are each formed in a rectangular shape as seen in a plan view,
the first and second electrostatic protection diodes are disposed so as to share one side, and
the third electrostatic protection diode is disposed so as to be contiguous evenly with the first and second electrostatic protection diodes.

4. The semiconductor device according to claim 2, wherein
the semiconductor device is a CAN transceiver,
the first signal terminal is a high-side bus input/output terminal, and
the second signal terminal is a low-side bus input/output terminal.

5. The semiconductor device according to claim 4, further comprising:
a high-side output circuit configured to switch between a conducting state and a cut-off state a path between the first signal terminal and a supply terminal; and
a low-side output circuit configured to switch between a conducting state and a cut-off state a path between the second signal terminal and ground terminal.

6. The semiconductor device according to claim 5, wherein
the high-side output circuit includes a first reverse current prevention diode configured to prevent a reverse current from the first signal terminal to the supply terminal.

7. The semiconductor device according to claim 5, wherein
the low-side output circuit includes a second reverse current prevention diode configured to prevent a reverse current from the ground terminal to the second signal terminal.

8. The semiconductor device according to claim 5, wherein
the low-side output circuit shares the second electrostatic protection diode as the second reverse current prevention diode configured to prevent a reverse current from the ground terminal to the second signal terminal.

9. The semiconductor device according to claim 1, wherein
the lateral NDMOS transistor includes:
a semiconductor layer of a first conductivity type having a main face and including a device region;
a base region of a second conductivity type formed in the device region, in a superficial part of the main face;
a source region of the first conductivity type formed in a superficial part of the base region at an interval inward from an edge part of the base region, the source region demarcating a channel region from the semiconductor layer;
a base contact region of the second conductivity type formed in a superficial part of the base region, in a region different from the source region, the base contact region having a dopant concentration more than a dopant concentration in the base region;
a well region of the first conductivity type formed in the device region, in a superficial part of the main face at an interval from the base region, the well region demarcating a drift region from the base region;
a drain region of the first conductivity type formed in a superficial part of the well region;
a dopant region of the second conductivity type formed in a superficial part of the well region and electrically connected to the drain region; and
a gate structure having:
a gate insulation film coating the channel region on the main face; and
a gate electrode on the gate insulation film, the gate electrode facing the channel region and electrically connected to the source region and to the base contact region.

10. A semiconductor device comprising:
a first signal terminal;
a second signal terminal;
a ground terminal;
at least one first electrostatic protection diode configured to be connected, with a first polarity, between the first signal terminal and an internal node;
at least one second electrostatic protection diode configured to be connected, with the first polarity, between the second signal terminal and the internal node; and
at least one third electrostatic protection diode configured to be connected, with a second polarity reverse to the first polarity, between the internal node and the ground terminal.
